(19) United States
(12) Patent Application Publication
(10) Pub. No.: US 2026/0361053 A1
(43) Pub. Date: Nov. 12, 2026

(54) SURFACE EMITTING LASER

(71) Applicant: Sony Group Corporation, Tokyo (JP)

(72) Inventors: Tomohiro MAKINO, Kanagawa (JP); Tatsushi HAMAGUCHI, Kanagawa (JP)

(21) Appl. No.: 19/131,725

(22) PCT Filed: Nov. 13, 2023
(86) PCT No.: PCT/JP2023/040712

§ 371 Date: May 21, 2025

(30) Foreign Application Priority Data
Dec. 26, 2022 (JP) 2022-208174

(51) Int. Cl. H01S 5/183; H01S 5/042; H01S 5/068; H01S 5/10

(52) U.S. Cl. CPC H01S 5/18361; H01S 5/04256; H01S 5/06821; H01S 5/1039; H01S 5/1053; H01S 5/18355

(57) ABSTRACT

Provided is a surface emitting laser capable of stably controlling a polarization direction while suppressing a decrease in efficiency.

A surface emitting laser according to the present technology includes a resonator including: first and second reflecting mirrors laminated on each other; and an active layer disposed between the first and second reflecting mirrors, the resonator further including a reflection portion having a reflection surface, in which the reflection portion is located outside a current injection region of the active layer in plan view, and a normal line of the reflection surface is not parallel to an emission direction. According to the present technology, it is possible to provide a surface emitting laser capable of stably controlling a polarization direction while suppressing a decrease in efficiency.

### TECHNICAL FIELD

The technology according to the present disclosure (hereinafter also referred to as “the present technology”) relates to a surface emitting laser.

### BACKGROUND ART

Conventionally, a vertical cavity surface emitting laser (VCSEL) in which an active layer is sandwiched between first and second reflecting mirrors is known.

Some conventional surface emitting lasers can control a polarization direction of emitted light.

For example, in a surface emitting laser described in Patent Document 1, a fine periodic structure portion formed on an emission surface controls a polarization direction of emitted light.

For example, in the surface emitting laser described in Patent Document 2, the polarization direction of the emitted light is controlled by applying distortion to the active layer using the arrangement of the two divided portions of the emission protective film and the metal electrode having shape anisotropy.

### CITATION LIST

### Patent Document

Patent Document 1: Japanese Patent Application Laid-Open No. 2014-029979

Patent Document 2: Japanese Patent Application Laid-Open No. 2016-025292

### SUMMARY OF THE INVENTION

### Problems to be Solved by the Invention

In the surface emitting laser described in Patent Document 1, there is room for improvement in suppressing a decrease in efficiency. In the surface emitting laser described in Patent Document 2, there is room for improvement in stably controlling the polarization direction of the emitted light.

Therefore, a main object of the present technology is to provide a surface emitting laser capable of stably controlling a polarization direction of emitted light while suppressing a decrease in efficiency.

### Solutions to Problems

The present technology provides a surface emitting laser including a resonator including:
first and second reflecting mirrors laminated on each other; and
an active layer disposed between the first and second reflecting mirrors,
the resonator further including a reflection portion having a reflection surface, in which
the reflection portion is located outside a current injection region of the active layer in plan view, and
a normal line of the reflection surface is not parallel to an emission direction.

The resonator may have a current confinement region that sets the current injection region.

A smaller one of angles formed by the normal line and the emission direction may be 30° or more and 90° or less.

The reflection surface may be at least a part of a side surface of the resonator or at least a part of a side surface of a groove provided in the resonator.

The reflection surface may be an entire side surface of the resonator or an entire side surface of a groove provided in the resonator.

The reflection surface may be constituted by a cleaved surface.

The reflection surface includes at least one of an interface between a semiconductor and air, an interface between a semiconductor and a dielectric, an interface between a dielectric and a semiconductor having a laminated structure, an interface between a semiconductor and a metal, an interface between a dielectric and air, or an interface between a semiconductor and a semiconductor having a laminated structure.

The resonator may include a slab waveguide that propagates light in a direction non-parallel to the emission direction.

The resonator may have a refractive index distribution in a lateral direction of 5% or less.

A length of the reflection surface in the emission direction may occupy 25% or more of a length of the resonator in the emission direction.

The resonator may include a substrate disposed between the first reflecting mirror and the active layer, and the substrate may have at least a part of the reflection surface.

The resonator may include a plurality of the reflection portions.

Each of the reflection surfaces of at least two of the plurality of the reflection portions may be non-parallel to each other.

Each of the reflection surfaces of at least two of the plurality of the reflection portions may be parallel to each other.

The active layer may have a plurality of the current injection regions, and the plurality of the reflection portions may be provided individually corresponding to the plurality of the current injection regions.

The active layer may have a plurality of the current injection regions, and the plurality of the reflection portions may be provided in common in the plurality of the current injection regions.

The active layer may have a plurality of the current injection regions, and some of the plurality of the reflection portions may be provided in common in others of the plurality of the current injection regions, and the others of the plurality of the reflection portions may be provided in common in the others of the plurality of the current injection regions.

The active layer may have a plurality of the current injection regions, and the reflection portion may be provided in common in the plurality of the current injection regions.

A shortest distance in an in-plane direction between an outer edge of the first reflecting mirror and the reflection surface may be 1000 μm or less.

A distance in an in-plane direction between a center of the current injection region and the reflection surface may be 1000 μm or less.

### BRIEF DESCRIPTION OF DRAWINGS

FIG. 1 is a cross-sectional view of a surface emitting laser according to Example 1 of one embodiment of the present technology.

FIG. 2 is a plan view of a surface emitting laser according to Example 1 of one embodiment of the present technology.

FIG. 3 is a flowchart for explaining an example of a method for manufacturing the surface emitting laser of FIG. 1.

FIGS. 4A and 4B are cross-sectional views for each process of an example of the method for manufacturing the surface emitting laser of FIG. 1.

FIGS. 5A and 5B are cross-sectional views for each process of an example of the method for manufacturing the surface emitting laser of FIG. 1.

FIGS. 6A and 6B are cross-sectional views for each process of an example of the method for manufacturing the surface emitting laser of FIG. 1.

FIGS. 7A and 7B are cross-sectional views for each process of an example of the method for manufacturing the surface emitting laser of FIG. 1.

FIG. 8 is a cross-sectional view for each process of an example of the method for manufacturing the surface emitting laser of FIG. 1.

FIG. 9 is a cross-sectional view of a surface emitting laser according to Example 2 of one embodiment of the present technology.

FIG. 10 is a plan view of a surface emitting laser according to Example 2 of one embodiment of the present technology.

FIG. 11 is a cross-sectional view of a surface emitting laser according to Example 3 of one embodiment of the present technology.

FIG. 12 is a plan view of a surface emitting laser according to Example 3 of one embodiment of the present technology.

FIG. 13 is a cross-sectional view of a surface emitting laser according to Example 4 of one embodiment of the present technology.

FIG. 14 is a plan view of a surface emitting laser according to Example 4 of one embodiment of the present technology.

FIG. 15 is a cross-sectional view of a surface emitting laser according to Example 5 of one embodiment of the present technology.

FIG. 16 is a plan view of a surface emitting laser according to Example 5 of one embodiment of the present technology.

FIGS. 17A and 17B are cross-sectional views (Part 1 and Part 2) of a surface emitting laser according to Example 6 of one embodiment of the present technology, respectively.

FIG. 18 is a plan view of a surface emitting laser according to Example 6 of one embodiment of the present technology.

FIGS. 19A and 19B are cross-sectional views (Part 1 and Part 2) of a surface emitting laser according to Example 7 of one embodiment of the present technology, respectively.

FIG. 20 is a plan view of a surface emitting laser according to Example 7 of one embodiment of the present technology.

FIG. 21 is a cross-sectional view of a surface emitting laser according to Example 8 of one embodiment of the present technology.

FIG. 22 is a plan view of a surface emitting laser according to Example 8 of one embodiment of the present technology.

FIG. 23 is a flowchart for explaining an example of a method for manufacturing the surface emitting laser of FIG. 21.

FIGS. 24A and 24B are cross-sectional views for each process of an example of the method for manufacturing the surface emitting laser of FIG. 21.

FIGS. 25A and 25B are cross-sectional views for each process of an example of the method for manufacturing the surface emitting laser of FIG. 21.

FIGS. 26A and 26B are cross-sectional views for each process of an example of the method for manufacturing the surface emitting laser of FIG. 21.

FIGS. 27A and 27B are cross-sectional views for each process of an example of the method for manufacturing the surface emitting laser of FIG. 21.

FIG. 28 is a cross-sectional view for each process of an example of the method for manufacturing the surface emitting laser of FIG. 21.

FIG. 29 is a cross-sectional view of a surface emitting laser according to Example 9 of one embodiment of the present technology.

FIG. 30 is a plan view of a surface emitting laser according to Example 9 of one embodiment of the present technology.

FIGS. 31A and 31B are cross-sectional views for each process of an example of the method for manufacturing the surface emitting laser of FIG. 29.

FIGS. 32A and 32B are cross-sectional views for each process of an example of the method for manufacturing the surface emitting laser of FIG. 29.

FIG. 33 is a cross-sectional view for each process of an example of the method for manufacturing the surface emitting laser of FIG. 29.

FIG. 34 is a cross-sectional view of a surface emitting laser according to Example 10 of one embodiment of the present technology.

FIG. 35 is a plan view of a surface emitting laser according to Example 10 of one embodiment of the present technology.

FIG. 36 is a cross-sectional view of a surface emitting laser according to Example 11 of one embodiment of the present technology.

FIG. 37 is a plan view of a surface emitting laser according to Example 11 of one embodiment of the present technology.

FIG. 38 is a plan view of a surface emitting laser according to Example 12 of one embodiment of the present technology.

FIG. 39 is a plan view of a surface emitting laser according to Example 13 of one embodiment of the present technology.

FIG. 40 is a plan view of a surface emitting laser according to Example 14 of one embodiment of the present technology.

FIG. 41 is a plan view of a surface emitting laser according to Example 15 of one embodiment of the present technology.

FIG. 42 is a cross-sectional view of a surface emitting laser according to Example 16 of one embodiment of the present technology.

FIG. 43 is a cross-sectional view of a surface emitting laser according to Example 17 of one embodiment of the present technology.

FIG. 44 is a cross-sectional view of a surface emitting laser according to Example 18 of one embodiment of the present technology.

FIG. 45 is a cross-sectional view of a surface emitting laser according to Example 19 of one embodiment of the present technology.

FIG. 46 is a cross-sectional view of a surface emitting laser according to Example 20 of one embodiment of the present technology.

FIG. 47 is a cross-sectional view of a surface emitting laser according to Example 21 of one embodiment of the present technology.

FIG. 48 is a cross-sectional view of a surface emitting laser according to Example 22 of one embodiment of the present technology.

FIG. 49 is a cross-sectional view of a surface emitting laser according to Example 23 of one embodiment of the present technology.

FIG. 50 is a cross-sectional view of a surface emitting laser according to Example 24 of one embodiment of the present technology.

FIG. 51 is a cross-sectional view of a surface emitting laser according to Example 25 of one embodiment of the present technology.

FIG. 52 is a cross-sectional view of a surface emitting laser according to Example 26 of one embodiment of the present technology.

FIG. 53 is a diagram illustrating an application example of the surface emitting laser according to the present technology to a distance measurement apparatus.

FIG. 54 is a block diagram depicting an example of schematic configuration of a vehicle control system.

FIG. 55 is an explanatory diagram illustrating an example of installation positions of distance measurement apparatuses.

### MODE FOR CARRYING OUT THE INVENTION

Hereinafter, preferred embodiments of the present technology will be described in detail with reference to the accompanying drawings. Note that, in the present specification and the drawings, components having substantially the same functional configuration are denoted by the same reference signs, and redundant description is omitted. The embodiments described below illustrate representative embodiments of the present technology, and the scope of the present technology is not narrowly interpreted by these embodiments. In the present specification, even in a case where it is described that the surface emitting laser according to the present technology exhibits a plurality of effects, it is sufficient that the surface emitting laser according to the present technology exhibits at least one effect. The effects described in the present specification are merely examples and are not limited, and other effects may be provided.

In addition, description will be given in the following order.
0. Introduction
1. Surface Emitting Laser According to Example 1 of One Embodiment of Present Technology
2. Surface Emitting Laser According to Example 2 of One Embodiment of Present Technology
3. Surface Emitting Laser According to Example 3 of One Embodiment of Present Technology
4. Surface Emitting Laser According to Example 4 of One Embodiment of Present Technology
5. Surface Emitting Laser According to Example 5 of One Embodiment of Present Technology
6. Surface Emitting Laser According to Example 6 of One Embodiment of Present Technology
7. Surface Emitting Laser According to Example 7 of One Embodiment of Present Technology
8. Surface Emitting Laser According to Example 8 of One Embodiment of Present Technology
9. Surface Emitting Laser According to Example 9 of One Embodiment of Present Technology
10. Surface Emitting Laser According to Example 10 of One Embodiment of Present Technology
11. Surface Emitting Laser According to Example 11 of One Embodiment of Present Technology
12. Surface Emitting Laser According to Example 12 of One Embodiment of Present Technology
13. Surface Emitting Laser According to Example 13 of One Embodiment of Present Technology
14. Surface Emitting Laser According to Example 14 of One Embodiment of Present Technology
15. Surface Emitting Laser According to Example 15 of One Embodiment of Present Technology
16. Surface Emitting Laser According to Example 16 of One Embodiment of Present Technology
17. Surface Emitting Laser According to Example 17 of One Embodiment of Present Technology
18. Surface Emitting Laser According to Example 18 of One Embodiment of Present Technology
19. Surface Emitting Laser According to Example 19 of One Embodiment of Present Technology
20. Surface Emitting Laser According to Example 20 of One Embodiment of Present Technology
21. Surface Emitting Laser According to Example 21 of One Embodiment of Present Technology
22. Surface Emitting Laser According to Example 22 of One Embodiment of Present Technology
23. Surface Emitting Laser According to Example 23 of One Embodiment of Present Technology
24. Surface Emitting Laser According to Example 24 of One Embodiment of Present Technology
25. Surface Emitting Laser According to Example 25 of One Embodiment of Present Technology
26. Surface Emitting Laser According to Example 26 of One Embodiment of Present Technology
27. Modifications of Present Technology
28. Application Example to Electronic Equipment
29. Example in Which Surface Emitting Laser Is Applied to Distance Measurement Apparatus
30. Example in Which Distance Measurement Apparatus Is Mounted on Mobile Body

### 0. Introduction

Conventionally, in a vertical cavity surface emitting laser (VCSEL), since a crystal orientation (c plane) and a structure of an element have symmetry in a plane, a polarization direction of emitted light is not determined, and light in various polarization directions is emitted depending on a sample. Furthermore, a phenomenon in which the polarization direction changes during driving has also been confirmed. Depending on the application in which the VCSEL is used as a light source, it is desirable that the polarization direction can be controlled.

For example, there has been proposed a technique of obtaining emitted light polarized in one direction by giving a difference in refractive index and reflectance in the horizontal/vertical direction by a grating (fine periodic structure portion) (see, for example, Patent Document 1). However, for example, in Patent Document 1, since a grating is provided on the emission surface (at a position overlapping the current injection region of the active layer in plan view), there is a concern about a decrease in efficiency.

For example, attempts have been made to perform polarization control by applying distortion in one direction to the active layer or applying a loss having anisotropy in a plane to the inside of the resonator (see, for example, Patent Document 2), but a phenomenon in which the polarization angle varies for each sample, and takes a binary value of, for example, 0°/90° with respect to a target, or a phenomenon in which the polarization angle rotates by 90° during driving has been confirmed. That is, for example, in Patent Document 2, there is a concern that the polarization direction cannot be stably controlled.

Therefore, as a result of intensive studies, the inventors have developed the surface emitting laser according to the present technology as a surface emitting laser capable of stably controlling the polarization direction of the emitted light while suppressing a decrease in efficiency.

Specifically, the inventors have succeeded in stably controlling the polarization direction by providing a resonator with a function of propagating light in a direction other than the vertical direction (emission direction) in the resonator. Since this function is realized by the reflection portion having the reflection surface provided at a position deviated from the current injection region of the active layer of the resonator in plan view, it is possible to suppress a decrease in efficiency.

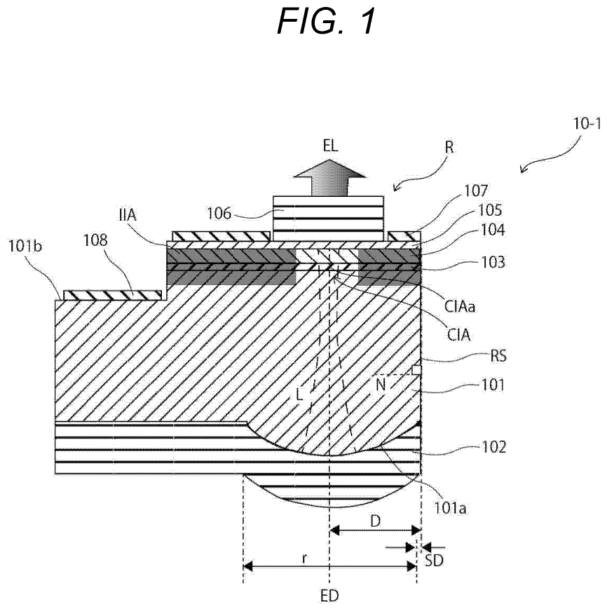

Hereinafter, one embodiment of a surface emitting laser according to the present technology will be described in detail with some examples. Hereinafter, for convenience, the upper side in the cross-sectional view of FIG. 1 and the like will be described as an upper side, and the lower side will be described as a lower side.

### 1. Surface Emitting Laser According to Example 1 of One Embodiment of Present Technology

Hereinafter, a surface emitting laser according to Example 1 of one embodiment of the present technology will be described with reference to the drawings.

### Configuration of Surface Emitting Laser

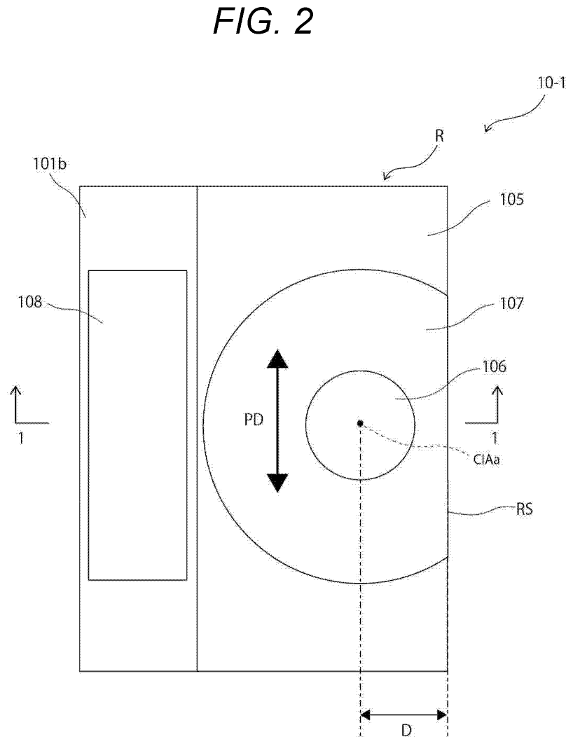

FIG. 1 is a cross-sectional view of a surface emitting laser 10-1 according to Example 1 of one embodiment of the present technology. FIG. 2 is a plan view of a surface emitting laser 10-1.

### Overall Configuration

As an example, as illustrated in FIG. 1, the surface emitting laser 10-1 includes a resonator R including first and second reflecting mirrors 102 and 106 laminated on each other and an active layer 103 disposed between the first and second reflecting mirrors 102 and 106. That is, the surface emitting laser 10-1 is a vertical cavity surface emitting laser (VCSEL). The surface emitting laser 10-1 is driven by, for example, a laser driver. Hereinafter, the direction in which the first and second reflecting mirrors 102 and 106 are laminated is also referred to as a “laminating direction”.

The oscillation wavelength of the surface emitting laser 10-1 is, for example, 405 nm, 447 nm, 457 nm, 488 nm, 515 nm, and a red band.

As an example, the first reflecting mirror 102 is a concave mirror, and second reflecting mirror 106 is a plane mirror. The resonator length of the resonator R, which is the distance between the first and second reflecting mirrors 102 and 106, is preferably, for example, 10 to 100 μm, and more preferably 25 to 50 μm. The total thickness of the surface emitting laser 10-1 is preferably, for example, 200 μm or less.

The resonator R further includes a substrate 101 disposed between the first reflecting mirror 102 and the active layer 103, a cladding layer 104 disposed between the active layer 103 and the second reflecting mirror 106, and a transparent conductive film 105 disposed between the cladding layer 104 and the second reflecting mirror 106. Further, the resonator R includes a reflection portion having a reflection surface RS.

The resonator R is provided with a circling ion implantation region IIA (high resistance region) as a current confinement region for setting a current injection region CIA (also referred to as “light emitting region”) of the active layer 103. As an example, the ion implantation region IIA exists in an upper portion of the substrate 101, and a peripheral region of the active layer 103 and the cladding layer 104. A region of the active layer 103 surrounded by the ion implantation region IIA is the current injection region CIA. The current injection region CIA is located between the first reflecting mirror 102 and the second reflecting mirror 106.

A bottom surface of the stepped portion formed in the resonator R is an electrode installation portion 101b. More specifically, the electrode installation portion 101b is an upper surface of the substrate 101 constituting a bottom surface of the stepped portion. The cathode electrode 108 is provided on the electrode installation portion 101b.

A circling anode electrode 107 surrounding the second reflecting mirror 106 is provided on a surface (upper surface) of the transparent conductive film 105 on a side opposite to the active layer 103 side (see FIG. 2). The anode electrode 107 surrounds the current injection region CIA in plan view.

### Substrate

The substrate 101 is an n-type cladding layer and is constituted by, for example, an n-GaN substrate. The substrate 101 has a lens-shaped portion 101a serving as a base of a concave mirror as the first reflecting mirror 102 on a surface (lower surface) opposite to the active layer 103 side. The lens-shaped portion 101a is located at a position corresponding to the current injection region CIA. In plan view, it is preferable that the center of the lens-shaped portion 101a and the center CIAa of the current injection region CIA coincide with each other. The lens-shaped portion 101a is convex to the side opposite to the active layer 103 side. The surface of the lens-shaped portion 101a is, for example, a curved surface such as a spherical surface or a paraboloid surface. The diameter r of the lens-shaped portion 101a is, for example, 30 to 50 μm. The radius of curvature (ROC) of the lens-shaped portion 101a is, for example, 10 to 400 μm.

### First Reflecting Mirror

Since the first reflecting mirror 102 is a concave mirror having positive power, the diffraction loss can be reduced by confinement of the optical field in the lateral direction. The first reflecting mirror 102 is constituted by, for example, a dielectric multilayer film reflecting mirror. The dielectric multilayer film reflecting mirror is constituted by, for example, Ta₂O₅/SiO₂, SiO₂/SiN, SiO₂/Nb₂O₅, or the like. In the dielectric multilayer film reflecting mirror, the thickness of each refractive index layer is, for example, 127 nm, and the number of pairs is 7.5 pairs or more.

The radius of curvature of the concave mirror as the first reflecting mirror 102 is, for example, 10 to 400 um. A plan view shape of the concave mirror as the first reflecting mirror 102 is, for example, a circular shape. As an example, the reflectance of the first reflecting mirror 102 is set to be slightly higher than the reflectance of the second reflecting mirror 106. That is, the second reflecting mirror 106 is a reflecting mirror on the emission side. Note that the reflectance of the second reflecting mirror 106 may be slightly higher than the reflectance of the first reflecting mirror 102, and the first reflecting mirror 102 may be used as a reflecting mirror on the emission side. The first reflecting mirror 102 may be a plane mirror.

### Active Layer

As an example, the active layer 103 includes a five-layered multiple quantum well structure in which an In_{0.04}Ga_{0.96}N layer (barrier layer) and an In_{0.16}Ga_{0.84}N layer (well layer) are laminated.

### Cladding Layer

The cladding layer 104 is a p-type cladding layer and is constituted by, for example, a p-GaN layer.

### Transparent Conductive Film

The transparent conductive film 105 functions as a buffer layer that enhances hole injection efficiency into the active layer 103 and prevents leakage. The transparent conductive film 105 is constituted by, for example, ITO, ITiO, AZO, ZnO, Sno, SnO₂, SnO₃, TiO, TiO₂, graphene, or the like.

### Second Reflecting Mirror

The plane mirror as the second reflecting mirror 106 is constituted by, for example, a dielectric multilayer film reflecting mirror. The dielectric multilayer film reflecting mirror is constituted by, for example, Ta₂O₅/SiO₂, SiN/SiO₂, or the like. The dielectric multilayer film reflecting mirror as the second reflecting mirror 106 has, for example, a circular shape in plan view. Note that the second reflecting mirror 106 is not limited to a plane mirror, and may be, for example, a concave mirror.

### Current Confinement Region

Examples of the ion species in the ion implantation region IIA as the current confinement region include B⁺⁺ and H⁺⁺. The ion implantation region IIA is formed by implanting high concentration ions (for example, B⁺⁺ or the like). The ion implantation region IIA has higher resistance (lower carrier conductivity) than a region surrounded by the ion implantation region IIA, and has a current confinement function. The current confinement diameter (diameter of the current confinement region) of the ion implantation region IIA is, for example, 3 to 10 μm. Note that the current confinement region is not limited to the ion implantation region, and may be, for example, an insulating region constituted by a dielectric or the like. Examples of the plan view shape of the current injection region include a circle, an ellipse, an I shape, an O shape (ring shape), and a polygon.

### Anode Electrode

The anode electrode 107 is constituted by, for example, at least one metal (including an alloy) selected from the group including Au, Ag, Pd, Pt, Ni, Ti, V, W, Cr, Al, Cu, Zn, Sn, and In. In a case where the anode electrode 107 has a laminated structure, the anode electrode is constituted by a material such as Ti/Au, Ti/Al, Ti/Al/Au, Ti/Pt/Au, Ni/Au, Ni/Au/Pt, Ni/Pt, Pd/Pt, or Ag/Pd. The anode electrode 107 is connected to an anode (positive electrode) of the laser driver.

### Cathode Electrode

The cathode electrode 108 is constituted by, for example, at least one metal (including an alloy) selected from the group including Au, Ag, Pd, Pt, Ni, Ti, V, W, Cr, Al, Cu, Zn, Sn, and In. In a case where the cathode electrode 108 has a laminated structure, the cathode electrode is constituted by a material such as Ti/Au, Ti/Al, Ti/Al/Au, Ti/Pt/Au, Ni/Au, Ni/Au/Pt, Ni/Pt, Pd/Pt, or Ag/Pd. The cathode electrode 108 is connected to a cathode (negative electrode) of a laser driver.

### Reflection Portion

Here, the reflection portion is constituted by the reflection surface RS. The reflection surface RS as the reflection portion is located outside the current injection region CIA of the active layer 103 in plan view. The normal line N of the reflection surface RS is not parallel to the emission direction ED. The reflection surface RS has a polarization control function that is a function of controlling the polarization direction of the emitted light in one direction.

The reflection surface RS is a part of a side surface of the resonator R including the first reflecting mirror 102, the substrate 101, the active layer 103, the cladding layer 104, the transparent conductive film 105, and the second reflecting mirror 106 (here, the side surface portion including the end face of the first reflecting mirror 102, the end face of the substrate 101, the end face of the active layer 103, the end face of the cladding layer 104, and the end face of the transparent conductive film 105). That is, the reflection surface RS includes an interface between a dielectric and air and an interface between a semiconductor and air.

The reflection surface RS is constituted by, for example, a cleaved surface. The reflection surface RS includes at least a specific crystal plane, and the defect region may occupy 80% or less, 50% or less, 20% or less, or 10% or less of the entire reflection surface RS.

The reflectance of the reflection surface RS as the reflection portion is, for example, preferably 10% or more, more preferably 20% or more, still more preferably 30% or more, still more preferably 40% or more, and still more sufficiently preferably 50% or more.

The length of the reflection surface RS in the emission direction ED accounts for preferably 25% or

more, more preferably 50% or more, and still more preferably 75% or more of the length of the resonator R in the emission direction ED.

The smaller angle formed by the normal line N of the reflection surface RS and the emission direction ED is preferably 30° or more and 90° or less, more preferably 45° or more and 90° or less, still more preferably 60° or more and 90° or less, and still more preferably 75° or more and 90° or less. Here, the smaller one is 90°.

Here, the shorter the distance D in the in-plane direction between the center CIAa of the current injection region CIA and the reflection surface RS, the larger the polarization control function by the reflection surface RS. Therefore, the distance D in the in-plane direction between the center of the current injection region CIA and the reflection surface RS is preferably 1000 μm or less, more preferably 500 μm or less, still more preferably 200 μm or less, still more preferably 100 μm or less, still more preferably 50 μm or less, and still more sufficiently preferably 20 μm or less. Since the reflection surface RS is outside the current injection region CIA, D≥1.5 μm is preferable, D≥3 μm is more preferable, and D≥5 μm is still more preferable.

On the other hand, when the distance D in the in-plane direction between the center CIAa of the current injection region CIA and the reflection surface RS is too short, there is a high possibility of affecting the laser oscillation. Therefore, the shortest distance SD in the in-plane direction between the outer edge of the concave mirror as the first reflecting mirror 102 and the reflection surface RS is preferably 1000 μm or less, more preferably 500 μm or less, still more preferably 200 μm or less, still more preferably 100 μm or less, still more preferably 50 μm or less, and still more sufficiently preferably 20 μm or less. Here, the reflection surface RS is located outside the outer edge of the concave mirror, and SD=D−r/2 holds. Note that the reflection surface RS may be located inside the outer edge of the concave mirror, and SD=r/2−D may hold, or the reflection surface RS may coincide with the outer edge of the concave mirror, and D=r/2 (SD=0) may hold.

The reflection surface RS causes optical confinement in the horizontal direction (also referred to as the in-plane direction of the substrate 101 and the lateral direction), and can generate light propagating in the horizontal direction. In the surface emitting laser 10-1, the electric field direction of coupleable light (coherent light) propagating in the vertical direction (the thickness direction of the substrate 101 and also referred to as the longitudinal direction) is affected by light propagating in the horizontal direction, and light in one polarization direction PD (horizontal direction parallel to reflection surface RS, see FIG. 2) is selectively oscillated. At this time, due to the coupling effect, even if the optical field distributed in the horizontal direction is wide, the light in one polarization direction PD can oscillate while maintaining the spatial phase relationship. Note that the shorter the distance D, the higher the reflectance of the reflection surface RS, the higher the coupling efficiency between light propagating in the vertical direction and light propagating in the horizontal direction.

In the surface emitting laser 10-1, a uniform lateral mode is generated by the action of the reflection surface RS, and light polarized in one direction (one polarization direction PD) is emitted. That is, the mode control and the polarization control can be performed by the reflection surface RS. The surface emitting laser 10-1 (for example, the surface emitting laser 10-1 having a current injection region of I-shape in plan view or O-shape in plan view) has a high polarization ratio of 90% or more (for example, 95%) due to the action of the reflection surface RS, and emits light polarized in one direction. Note that light having a polarization ratio of 100% is completely linearly polarized light.

By the way, in a conventional surface emitting laser (for example, a surface emitting laser having a current injection region of I-shape in plan view), when a current confinement diameter is large (for example, a major axis length of 100 to 200 μm), a lateral mode of emitted light is spatially localized. On the other hand, in the surface emitting laser 10-1 (for example, the surface emitting laser 10-1 having the current injection region of I-shape in plan view), it is known that the lateral mode of the emitted light is not spatially localized and is well-ordered even if the current confinement diameter is large (for example, 100 to 200 μm).

In the conventional surface emitting laser, the wavelength is different for each position of the emitted light, and a plurality of lateral modes oscillate disorderly. On the other hand, in the surface emitting laser 10-1, the spectrum has little or no spatial dependence, and oscillates in the same mode while maintaining the phase relationship in the entire light emitting region (current injection region CIA).

The resonator R includes at least a slab waveguide that propagates light in a direction (for example, a horizontal direction) non-parallel to the emission direction ED in the substrate 101. Specifically, in the resonator R, for example, the refractive index distribution (for example, 10% or more, preferably 15% or more) in the longitudinal direction is larger than the refractive index distribution (for example, 5% or less, preferably 3% or less) in the lateral direction in a region of 25% or more (preferably 50% or more, more preferably 75% or more) in the thickness direction (emission direction). Here, the resonator R can propagate light in the lateral direction while confining the light in the longitudinal direction in the slab waveguide. That is, light can be efficiently propagated in the lateral direction in the slab waveguide.

### Operation of Surface Emitting Laser

Hereinafter, the operation of the surface emitting laser 10-1 will be described. In the surface emitting laser 10-1, when a driving voltage is applied between the anode electrode 107 and the cathode electrode 108 by the laser driver, a current flows into the resonator R from the anode side of the laser driver via the anode electrode 107. The flowed current passes through the transparent conductive film 105 and is injected into the active layer 103 while being narrowed in the ion implantation region IIA. At this time, the active layer 103 emits light, and the light L reciprocates (at this time, the light L is reflected while being condensed in the vicinity of the active layer 103 by the concave mirror as the first reflecting mirror 102, and is reflected toward the active layer 103 as parallel light or weak diffused light by the plane mirror as the second reflecting mirror 106) while being amplified by the active layer 103 between the first and second reflecting mirrors 102 and 106, and is emitted from the second reflecting mirror 106 as emitted light EL (laser light) when the oscillation condition is satisfied. At this time, light propagates in the lateral direction in the slab waveguide due to optical confinement in the lateral direction by the reflection surface RS, the light and the light L propagating in the longitudinal direction are coupled, and the light in one polarization direction PD selectively oscillates while maintaining a spatial phase relationship in the optical field. The current injected into the active layer 103 flows out from the cathode electrode 108 to the cathode side of the laser driver via the substrate 101.

### Method for Manufacturing Surface Emitting Laser

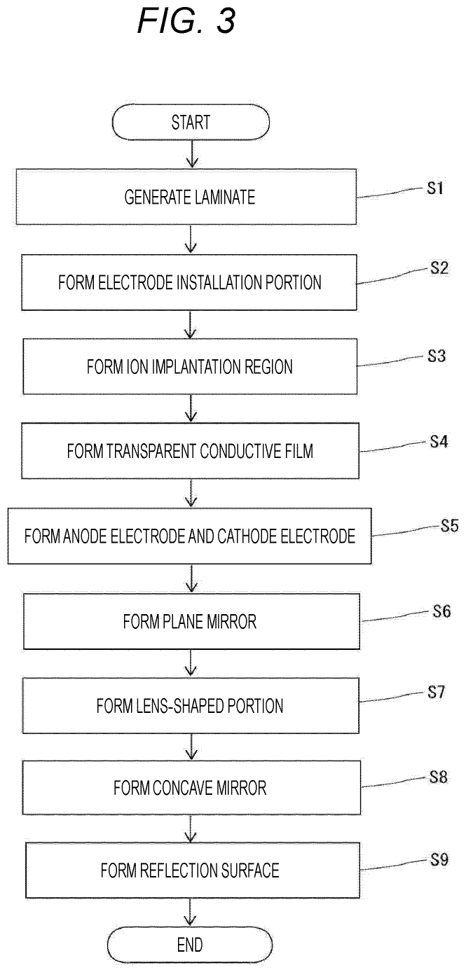

Hereinafter, an example of a method for manufacturing the surface emitting laser 10-1 will be described with reference to the flowchart of FIG. 3 and the like.

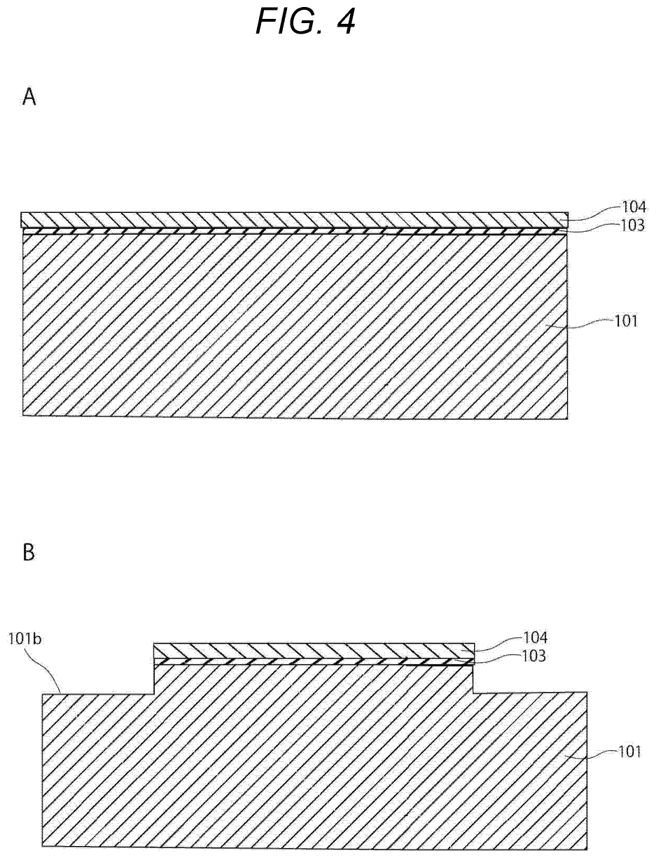

In the first step S1, a laminate is generated (see FIG. 4A). Specifically, the active layer 103 and the cladding layer 104 are grown in this order on the substrate 101 (for example, n-GaN substrate) in a growth chamber by a metal organic chemical vapor deposition method (MOCVD method) or a molecular beam epitaxy method (MBE method) to generate a laminate.

In the next step S2, the electrode installation portion 101b is formed (see FIG. 4B). Specifically, a resist pattern covering a portion other than the portion where the electrode installation portion 101b is formed on the laminate is formed, and the laminate is etched using the resist pattern as a mask. At this time, etching is performed until the etching bottom surface is positioned in the substrate 101. As a result, a stepped portion having the electrode installation portion 101b as a bottom surface is formed on the laminate.

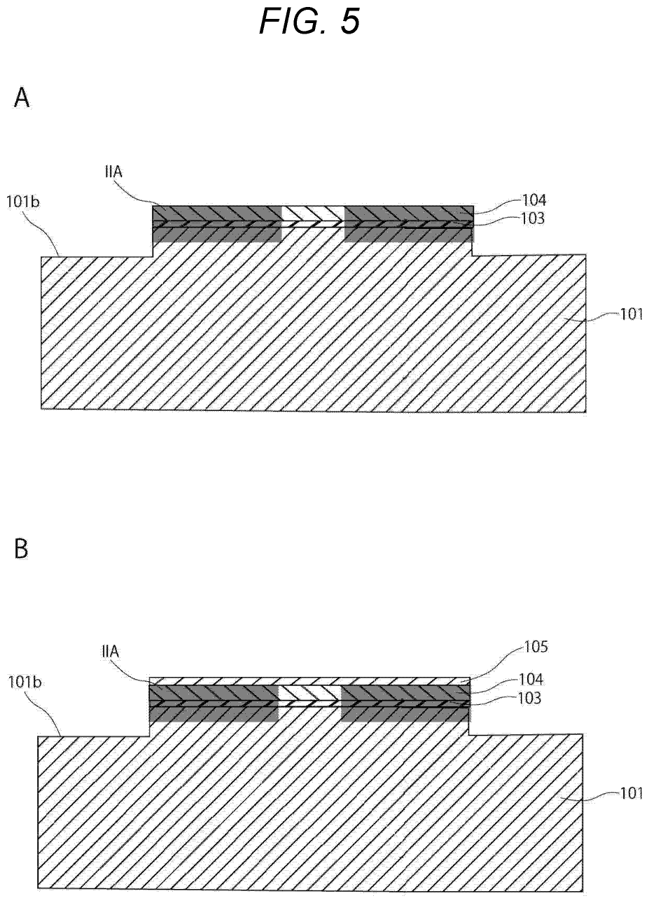

In the next step S3, the ion implantation region IIA is formed (see FIG. 5A). Specifically, a protective film constituted by resist, SiO₂, or the like is formed to cover a portion other than the portion where the ion implantation region IIA is formed on the laminate, and ions (for example, B⁺⁺) are implanted into the laminate from the cladding layer 104 side using the protective film as a mask. At this time, it is assumed that the implantation depth of the ion implantation reaches the inside of the substrate 101.

In the next step S4, the transparent conductive film 105 is formed (see FIG. 5B). Specifically, first, the transparent conductive film 105 is formed on the entire surface by, for example, a vacuum vapor deposition method, sputtering, or the like. Next, a resist pattern covering only the transparent conductive film 105 on the cladding layer 104 is formed, and etching is performed using the resist pattern as a mask to leave only the transparent conductive film 105 on the cladding layer 104.

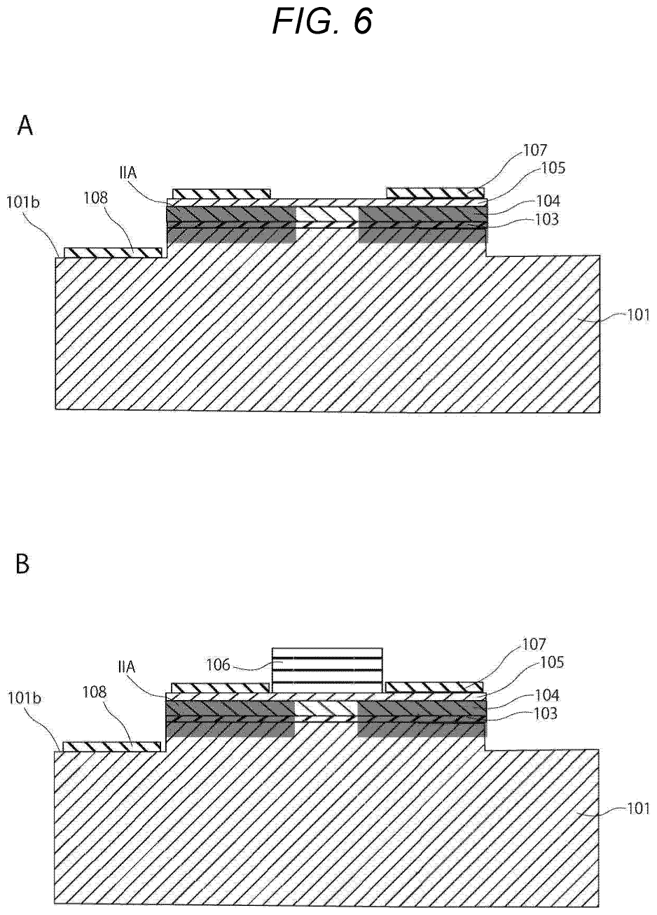

In the next step S5, the anode electrode 107 and the cathode electrode 108 are formed (see FIG. 6A). Specifically, for example, a lift-off method is used to form the anode electrode 107 in a circular shape on the transparent conductive film 105, and form the cathode electrode 108 on the electrode installation portion 101b. For the deposition of the electrode material at this time, for example, a vacuum vapor deposition method, sputtering, or the like is used.

In the next step S6, a plane mirror as the second reflecting mirror 106 is formed (see FIG. 6B). Specifically, first, a dielectric multilayer film as a material of the second reflecting mirror 106 is formed on the entire surface by, for example, a vacuum vapor deposition method, a sputtering method, a CVD method, or the like. Next, a resist pattern covering only the dielectric multilayer film to be the second reflecting mirror 106 is formed, and etching is performed using the resist pattern as a mask to leave only the dielectric multilayer film to be the second reflecting mirror 106.

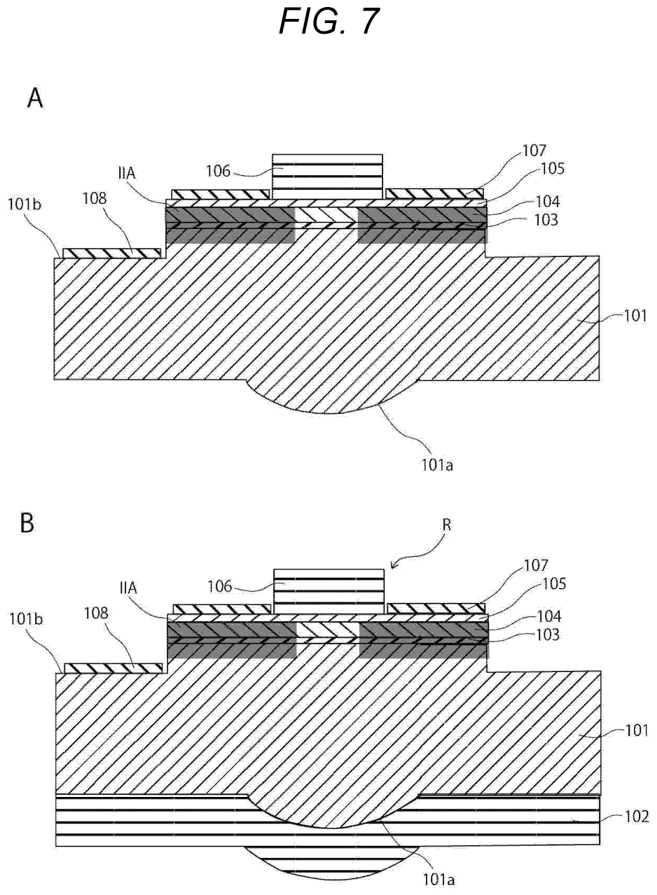

In the next step S7, the lens-shaped portion 101a is formed (see FIG. 7A). Specifically, first, a resist is formed at a portion where the lens-shaped portion 101a is to be formed on the back surface of the substrate 101 by photolithography. Next, for example, the resist is formed into a lens shape (for example, a substantially hemispherical shape) by reflow at a temperature of 200 °C. Next, etching is performed using a resist as a mask to form the lens-shaped portion 101a in, for example, a substantially hemispherical shape.

In the next step S8, a concave mirror as the first reflecting mirror 102 is formed (see FIG. 7B).

Specifically, the material of the first reflecting mirror 102 (for example, a dielectric multilayer film) is formed on the back surface of the substrate 101 on which the lens-shaped portion 101a is formed by, for example, a vacuum vapor deposition method, a sputtering method, a CVD method, or the like. As a result, a concave mirror having a shape following the lens-shaped portion 101a is formed.

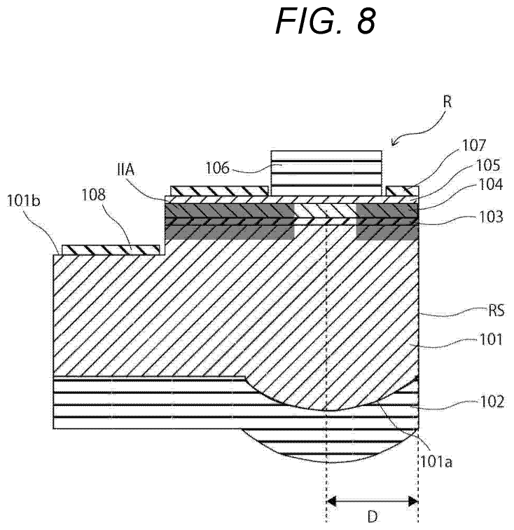

In the next step S9, the reflection surface RS is formed (see FIG. 8). Specifically, a linear scratch is made with a diamond cutter at a cleavage position where the reflection surface RS is to be formed in the laminate on which the concave mirror is formed. Subsequently, pressure is applied to the laminate from the side opposite to the surface having the linear scratches, and the scratched portion is divided so as to open. As a result, the resonator R is broken along the scratch to form a cleaved surface as the reflection surface RS. As a result, the surface emitting laser 10-1 is generated. Thereafter, the surface emitting laser 10-1 is mounted on, for example, a CAN package. More specifically, the surface of the surface emitting laser 10-1 on the first reflecting mirror 102 side is soldered to the CAN package.

### Effects of Surface Emitting Laser

Hereinafter, effects of the surface emitting laser 10-1 according to Example 1 of one embodiment of the present technology will be described.

The surface emitting laser 10-1 includes a resonator R including first and second reflecting mirrors 102 and 106 laminated on each other and an active layer 103 disposed between the first and second reflecting mirrors 102 and 106, and the resonator R includes a reflection portion having a reflection surface RS. The reflection portion is located outside the current injection region CIA of the active layer 103 in plan view, and the normal line N of the reflection surface RS is not parallel to the emission direction ED.

In this case, in the resonator R, light propagates in a direction (for example, the lateral direction) non-parallel to the emission direction by the reflection portion due to optical confinement in the direction (for example, the lateral direction) non-parallel to the emission direction by the reflection portion, and the light and the light propagating in the longitudinal direction are coupled, whereby the polarization direction can be stably controlled. Since the reflection portion is located outside the current injection region CIA in plan view, it is possible to suppress a decrease in efficiency.

As a result, according to the surface emitting laser 10-1, it is possible to provide a surface emitting laser capable of stably controlling the polarization direction of the emitted light while suppressing a decrease in efficiency.

On the other hand, there has been proposed a method of obtaining a polarization control function by applying distortion to an active layer using the arrangement of an anisotropic emission protective film and a metal electrode having a major axis and a minor axis (see, for example, Patent Document 2). For example, in Patent Document 2, in order to easily transmit stress to the active layer, the metal electrode is divided into two to increase the area where the emission protective film is in contact with the substrate.

However, Patent Document 2 has the following problems.
The arrangement of the electrodes is restricted.
An emission protective film is required.
Since a change in refractive index or expansion/contraction occurs due to distortion, the resonator length is different between the major axis direction and the minor axis direction of the protective film, and the polarization direction cannot be controlled in one direction, and a binary value may be obtained. Accordingly, there is a concern that the polarization direction during driving changes or the polarization direction varies in binary for each element.

The resonator R has an ion implantation region IIA as a current confinement region for setting the current injection region CIA. As a result, a current can be efficiently injected into the active layer 103.

The smaller angle formed by the normal line N of the reflection surface RS and the emission direction ED is 30° or more and 90° or less. As a result, the efficiency of optical confinement in the lateral direction by the reflection portion can be enhanced.

The reflection surface RS is a part of a side surface of the resonator R. Thus, it is not necessary to separately provide a member having a reflection surface.

The reflection surface RS is constituted by a cleaved surface. As a result, the reflectance of the reflection surface RS can be set to a value having the effectiveness of optical confinement. Furthermore, cleaving for forming a cleaved surface is a step subsequent to the manufacturing process of the surface emitting laser 10-1, and is effective in terms of low restriction and low difficulty.

On the other hand, for example, a method has been proposed in which a grating (fine periodic structure portion) is formed on a resonator to have a difference in refractive index and reflectance in a horizontal direction/a vertical direction, thereby obtaining emitted light polarized in one direction (see, for example, Patent Document 1). However, it is difficult to manufacture the grating itself, and the shorter the wavelength, the finer the structure becomes, and the processing difficulty becomes significantly high particularly in the wavelength band on the short wavelength side (for example, blue). In addition, since the grating is formed on the resonator, there is a concern about a decrease in efficiency.

The resonator R has a slab waveguide. As a result, light can be efficiently propagated in the lateral direction in the slab waveguide.

The resonator R has a refractive index distribution in the lateral direction of 5% or less (preferably 3% or less). As a result, light can be efficiently propagated in the lateral direction in the resonator R.

The length of the reflection surface RS in the emission direction occupies 25% or more of the length of the resonator R in the emission direction. As a result, light can be propagated in the lateral direction in a sufficient region in the longitudinal direction in the resonator R. Note that the longer the length of the reflection surface RS in the emission direction, the more the opportunity for coupling the light propagating in the longitudinal direction and the light propagating in the lateral direction in the resonator R, and thus the polarization direction can be more stably controlled.

The resonator R includes the substrate 101 disposed between the first reflecting mirror 102 and the active layer 103, and the substrate 101 has a part of the reflection surface RS. As a result, the length of the reflection surface RS in the emission direction can be secured relatively easily.

The first reflecting mirror 102 is a concave mirror. Thus, the diffraction loss can be reduced.

The shortest distance in the in-plane direction between the outer edge of the concave mirror as the first reflecting mirror 102 and the reflection surface RS is 1000 μm or less. This makes it possible to enhance polarization controllability while reducing the influence on laser oscillation.

The distance between the center CIAa of the current injection region CIA and the reflection surface RS in the in-plane direction is 1000 μm or less. Thus, polarization controllability can be sufficiently enhanced.

Furthermore, the surface emitting laser 10-1 also has the following several effects.
The lateral mode can also be controlled.
No fine processing is required.
The polarization direction does not change during driving.
Even in a case where the current injection region CIA has a wide area, it is possible to form an optical field with an in-plane phase.
By adjusting the distance from the center CIAa of the current injection region CIA to the reflection surface RS, it is possible to control the coupling efficiency between the light propagating in the longitudinal direction and the light propagating in the lateral direction.

The resonator length of the resonator R is 10 μm or more. As a result, an effective area of the reflection surface RS can be secured.

### 2. Surface Emitting Laser According to Example 2 of One Embodiment of Present Technology

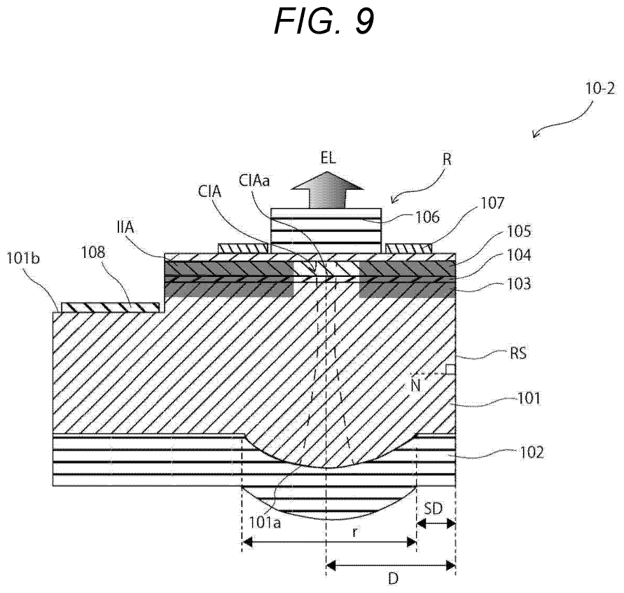

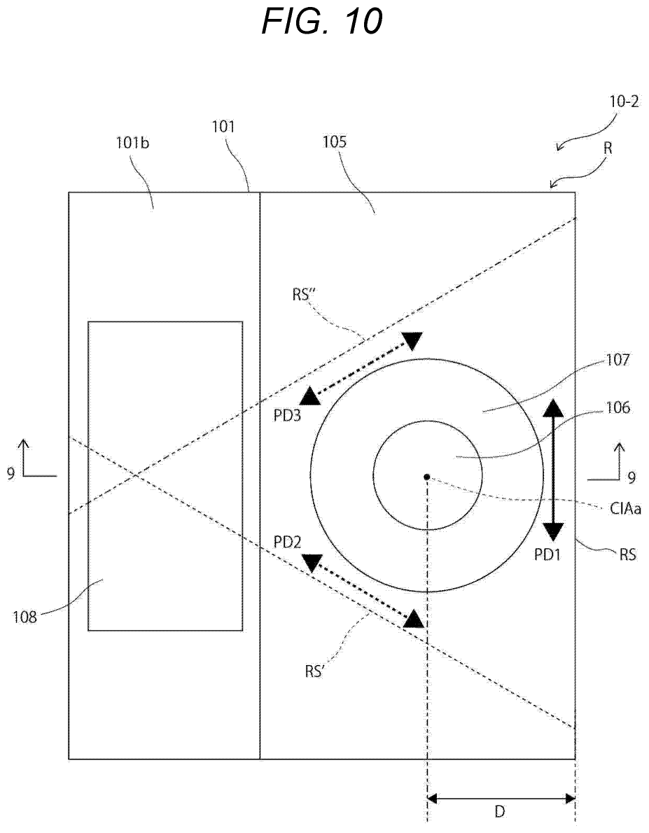

Hereinafter, a surface emitting laser according to Example 2 of one embodiment of the present technology will be described with reference to the drawings. FIG. 9 is a cross-sectional view of a surface emitting laser 10-2 according to Example 2 of one embodiment of the present technology. FIG. 10 is a plan view of the surface emitting laser 10-2 according to Example 2 of one embodiment of the present technology. FIG. 9 is a cross-sectional view taken along line 9-9 in FIG. 10.

In the surface emitting laser 10-2, as illustrated in FIGS. 9 and 10, the polarization direction can be controlled in a desired direction by introducing the concept of selectivity of the formation position of the reflection surface. However, in practice, there may be a position where a reflection surface having a polarization control function cannot be formed due to restriction by a crystal orientation.

For example, in a case where the reflection surface is the reflection surface RS indicated by a solid line in FIG. 10, the polarization direction can be controlled to one polarization direction PD1 which is a horizontal direction parallel to the reflection surface RS.

For example, in a case where the reflection surface is a reflection surface RS′ indicated by a broken line in FIG. 10, that is, a reflection surface forming an angle (for example, an acute angle) with respect to the reflection surface RS in plan view, it is possible to control the polarization direction to one polarization direction PD2 which is a horizontal direction parallel to the reflection surface RS′.

For example, in a case where the reflection surface is a reflection surface RS″ indicated by a two-dot chain line in FIG. 10, that is, a reflection surface forming an angle (for example, an acute angle) with respect to both the reflection surface RS and the reflection surface RS′ in plan view, it is possible to control the polarization direction to one polarization direction PD3 which is a horizontal direction parallel to the reflection surface RS″.

Any of the reflection surfaces RS, RS′, RS″ can be a cleaved surface. Each reflection surface is constituted by at least a specific crystal plane, and the defect region may occupy 80% or less, 50% or less, 20% or less, or 10% or less of the entire reflection surface. Here, the end face of the first reflecting mirror 102, the end face of the substrate 101, the end face of the active layer 103, the end face of the cladding layer 104, and the end face of the transparent conductive film 105 constitute each reflection surface.

The reflectance of each reflection surface is, for example, preferably 10% or more, more preferably 20% or more, still more preferably 30% or more, still more preferably 40% or more, and still more sufficiently preferably 50% or more.

The length of each reflection surface in the emission direction ED preferably accounts for 25% or more, more preferably 50% or more, and still more preferably 75% or more of the length of the resonator R in the emission direction ED.

The smaller angle formed by the normal line of each reflection surface and the emission direction is preferably 30° or more and 90° or less, more preferably 45° or more and 90° or less, still more preferably 60° or more and 90° or less, and yet still more preferably 75° or more and 90° or less. Here, the smaller one is 90°.

In the surface emitting laser 10-2, for example, in a case where the reflection surface is the reflection surface RS, the shortest distance SD in the in-plane direction between the outer edge of the concave mirror as the first reflecting mirror 102 and the reflection surface RS is preferably 1000 μm or less, more preferably 500 μm or less, still more preferably 200 μm or less, still more preferably 100 μm or less, still more preferably 50 μm or less, and still more sufficiently preferably 20 μm or less. In a case where the reflection surface is, for example, the reflection surface RS′ or the reflection surface RS″, similar argument to above holds.

In the surface emitting laser 10-2, for example, in a case where the reflection surface is the reflection surface RS, the distance D in the in-plane direction between the center CIAa of the current injection region CIA and the reflection surface RS is preferably 1000 μm or less, more preferably 500 μm or less, still more preferably 200 μm or less, still more preferably 100 μm or less, still more preferably 50 μm or less, and still more sufficiently preferably 20 μm or less. Here, D=r/2+SD holds. Note that D=r/2−SD may hold, or D=r/2 (SD=0) may hold. In a case where the reflection surface is, for example, the reflection surface RS′ or the reflection surface RS″, similar argument to above holds.

According to the surface emitting laser 10-2, effects similar to those of the surface emitting laser 10-1 according to Example 1 can be obtained, and the polarization direction can be controlled to a desired direction.

Note that, here, three reflection surfaces forming an acute angle with each other in a plan view are exemplified as the selection candidate of the reflection surface, but a plurality of reflection surfaces forming an angle (acute angle or obtuse angle) in a plan view and/or a plurality of reflection surfaces parallel with each other in a plan view can be selected as the selection candidate.

### 3. Surface Emitting Laser According to Example 3 of One Embodiment of Present Technology

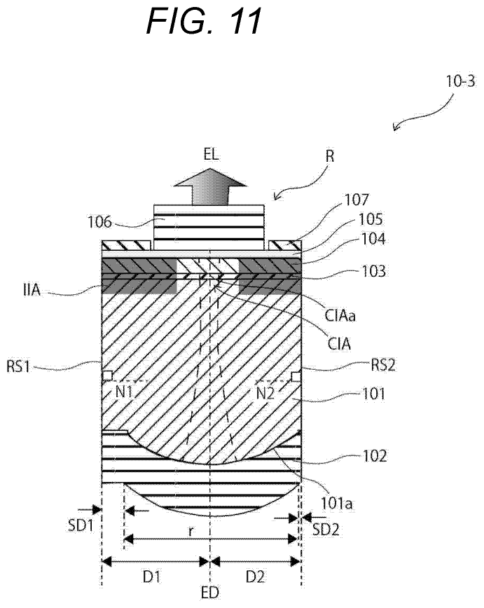

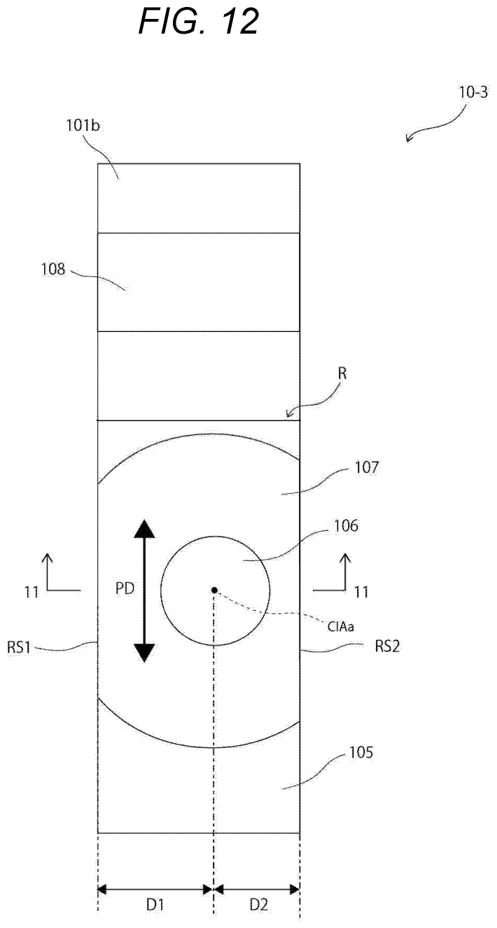

Hereinafter, a surface emitting laser according to Example 3 of one embodiment of the present technology will be described with reference to the drawings. FIG. 11 is a cross-sectional view of a surface emitting laser 10-3 according to Example 3 of one embodiment of the present technology. FIG. 12 is a plan view of the surface emitting laser 10-3 according to Example 3 of one embodiment of the present technology. FIG. 11 is a cross-sectional view taken along line 11-11 in FIG. 12.

As illustrated in FIGS. 11 and 12, the surface emitting laser 10-3 has a configuration substantially similar to the surface emitting laser 10-1 according to Example 1 except that it has a plurality of (for example, two) reflection surfaces as reflection portions.

As illustrated in FIGS. 11 and 12, the surface emitting laser 10-3 has first and second reflection surfaces RS1 and RS2. One part of one side surface and the other side surface facing each other of the resonator R is the first reflection surface RS1, and the other part is the second reflection surface RS2. The first and second reflection surfaces RS1 and RS2 are parallel to each other. Both the first and second reflection surfaces RS1 and RS2 can be cleaved surfaces. A smaller one of the angles formed by the normal line N1 of the first reflection surface RS1 and the emission direction ED is 90°. A smaller one of the angles formed by the normal line N2 of the second reflection surface RS2 and the emission direction ED is 90°. By optical confinement of the first and second reflection surfaces RS1 and RS2 in the lateral direction, the polarization direction can be controlled to one polarization direction PD which is a horizontal direction parallel to both the first and second reflection surfaces RS1 and RS2 (see FIG. 12).

As illustrated in FIG. 12, in the surface emitting laser 10-3, the electrode installation portion 101b is provided at a position adjacent to the resonator R in one polarization direction PD in the substrate 101 in plan view, and the cathode electrode 108 is provided on the electrode installation portion 101b.

The reflectances of the first and second reflection surfaces RS1 and RS2 may be the same or different.

In the surface emitting laser 10-3, the shortest distance SD1 in the in-plane direction (horizontal direction) between the outer edge of the concave mirror as the first reflecting mirror 102 and the first reflection surface RS1 is preferably 1000 μm or less, more preferably 500 μm or less, still more preferably 200 μm or less, still more preferably 100 μm or less, still more preferably 50 μm or less, and still more sufficiently preferably 20 μm or less. Here, SD1 is 15 μm or less.

In the surface emitting laser 10-3, the shortest distance SD2 in the in-plane direction (horizontal direction) between the outer edge of the concave mirror as the first reflecting mirror 102 and the second reflection surface RS2 is preferably 1000 μm or less, more preferably 500 μm or less, still more preferably 200 um or less, still more preferably 100 μm or less, still more preferably 50 μm or less, and still more sufficiently preferably 20 μm or less. Here, SD2 is 5 μm or less.

In the surface emitting laser 10-3, the distance D1 in the in-plane direction (horizontal direction) between the center CIAa of the current injection region CIA and the first reflection surface RS1 is preferably 1000 μm or less, more preferably 500 μm or less, still more preferably 200 μm or less, still more preferably 100 μm or less, still more preferably 50 μm or less, and still more sufficiently preferably 20 μm or less. Here, D1=r/2+SD1 holds. Note that D1=r/2−SD1 may hold, or D1=r/2 (SD1=0) may hold.

In the surface emitting laser 10-3, the distance D2 in the in-plane direction (horizontal direction) between the center CIAa of the current injection region CIA and the second reflection surface RS2 is preferably 1000 μm or less, more preferably 500 μm or less, still more preferably 200 μm or less, still more preferably 100 μm or less, still more preferably 50 μm or less, and still more sufficiently preferably 20 μm or less. Here, D2=r/2+SD2 holds. Note that D2=r/2−SD2 may hold, or D2=r/2 (SD2=0) may hold. Here, D1≠D2, but D1=D2 may be satisfied.

According to the surface emitting laser 10-3, effects similar to those of the surface emitting laser 10-1 according to Example 1 can be obtained, and optical confinement in the lateral direction increases due to a synergistic effect of the first and second reflection surfaces RS1 and RS2, and polarization control performance can be improved.

### 4. Surface Emitting Laser According to Example 4 of One Embodiment of Present Technology

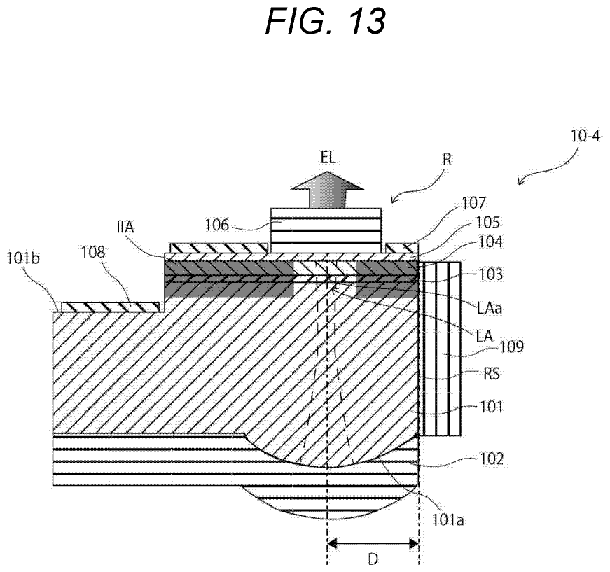

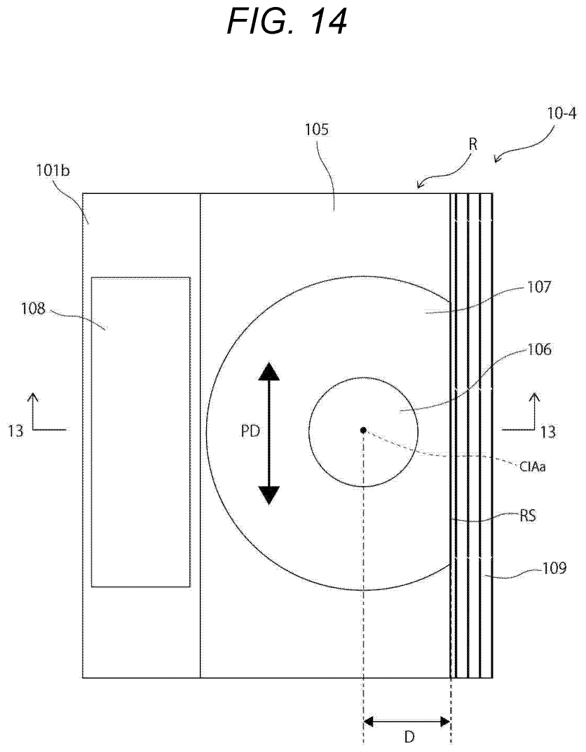

Hereinafter, a surface emitting laser according to Example 4 of one embodiment of the present technology will be described with reference to the drawings. FIG. 13 is a cross-sectional view of a surface emitting laser 10-4 according to Example 4 of one embodiment of the present technology. FIG. 14 is a plan view of the surface emitting laser 10-4 according to Example 4 of one embodiment of the present technology. FIG. 13 is a cross-sectional view taken along line 13-13 in FIG. 14.

As illustrated in FIGS. 13 and 14, the surface emitting laser 10-4 has a configuration similar to the surface emitting laser 10-1 according to Example 1 except that the reflection portion includes a multilayer film reflecting mirror 109 as a reflecting structure in addition to the reflection surface RS.

The multilayer film reflecting mirror 109 is provided on the reflection surface RS. More specifically, the multilayer film reflecting mirror 109 is provided across the end face of the substrate 101, the end face of the active layer 103, and the end face of the cladding layer 104 of the reflection surface RS. The multilayer film reflecting mirror 109 is, for example, a semiconductor multilayer film reflecting mirror, a dielectric multilayer film reflecting mirror, or the like. The multilayer film reflecting mirror 109 has a laminated structure (multilayer structure) in which a high refractive index layer and a low refractive index layer are alternately laminated in the horizontal direction (specifically, the 13-13 line direction in FIG. 14) at an optical thickness of ¼. That is, the reflection surface RS includes an interface between a dielectric and air and an interface between a semiconductor and a semiconductor having a laminated Structure or a dielectric having a laminated structure. Note that it is sufficient that the multilayer film reflecting mirror 109 is provided on at least a part of the reflection surface RS, and the arrangement and size can be appropriately changed.

The reflectance of the reflection portion including the reflection surface RS and the multilayer film reflecting mirror 109 is, for example, preferably 10% or more, more preferably 20% or more, still more preferably 30% or more, still more preferably 40% or more, and still more sufficiently preferably 50% or more.

According to the surface emitting laser 10-4, effects similar to those of the surface emitting laser 10-1 according to Example 1 can be obtained, and since the reflection portion includes the multilayer film reflecting mirror 109 in addition to the reflection surface RS, the reflectance of the reflection portion can be adjusted. To supplement, in the surface emitting laser 10-4, even if the reflectance of the reflection surface RS is low, the reflectance of the entire reflection portion can be increased.

### 5. Surface Emitting Laser According to Example 5 of One Embodiment of Present Technology

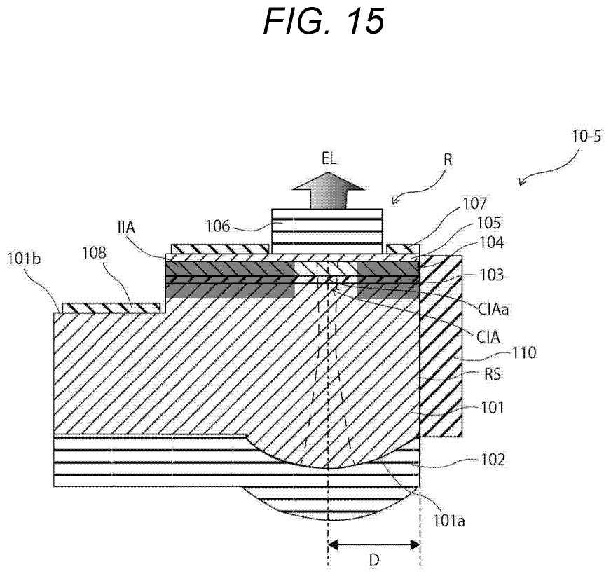

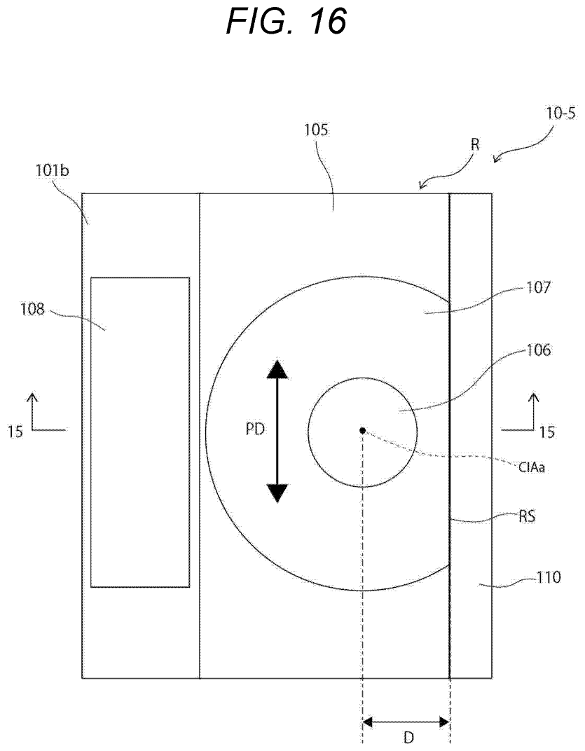

Hereinafter, a surface emitting laser according to Example 5 of one embodiment of the present technology will be described with reference to the drawings. FIG. 15 is a cross-sectional view of a surface emitting laser 10-5 according to Example 5 of one embodiment of the present technology. FIG. 16 is a plan view of the surface emitting laser 10-5 according to Example 5 of one embodiment of the present technology. FIG. 15 is a cross-sectional view taken along line 15-15 in FIG. 16.

As illustrated in FIGS. 15 and 16, the surface emitting laser 10-5 has a configuration similar to the surface emitting laser 10-1 according to Example 1 except that the reflection portion has a reflective film 110 as a reflecting structure in addition to the reflection surface RS.

The reflective film 110 is provided on the reflection surface RS. More specifically, the reflective film 110 is provided across the end face of the substrate 101, the end face of the active layer 103, the end face of the cladding layer 104, and the end face of the transparent conductive film 105 of the reflection surface RS. The reflective film 110 is, for example, a metal film or a dielectric film. That is, the reflection surface RS includes an interface between a dielectric and air and an interface between a semiconductor and a metal or a dielectric. The reflective film 110 may have a single-layer structure or a multilayer structure with a horizontal direction (specifically, a 15-15 line direction in FIG. 16) as a laminating direction. Note that it is sufficient that the reflective film 110 is provided on at least a part of the reflection surface RS, and the arrangement and size can be appropriately changed.

The reflectance of the reflection portion including the reflection surface RS and the reflective film 110 is, for example, preferably 10% or more, more preferably 20% or more, still more preferably 30% or more, still more preferably 40% or more, and still more sufficiently preferably 50% or more.

According to the surface emitting laser 10-5, effects similar to those of the surface emitting laser 10-1 according to Example 1 can be obtained, and since the reflection portion has the reflective film 110 in addition to the reflection surface RS, the reflectance of the reflection portion can be adjusted. To supplement, in the surface emitting laser 10-5, even if the reflectance of the reflection surface RS is low, the reflectance of the entire reflection portion can be increased.

### 6. Surface Emitting Laser According to Example 6 of One Embodiment of Present Technology

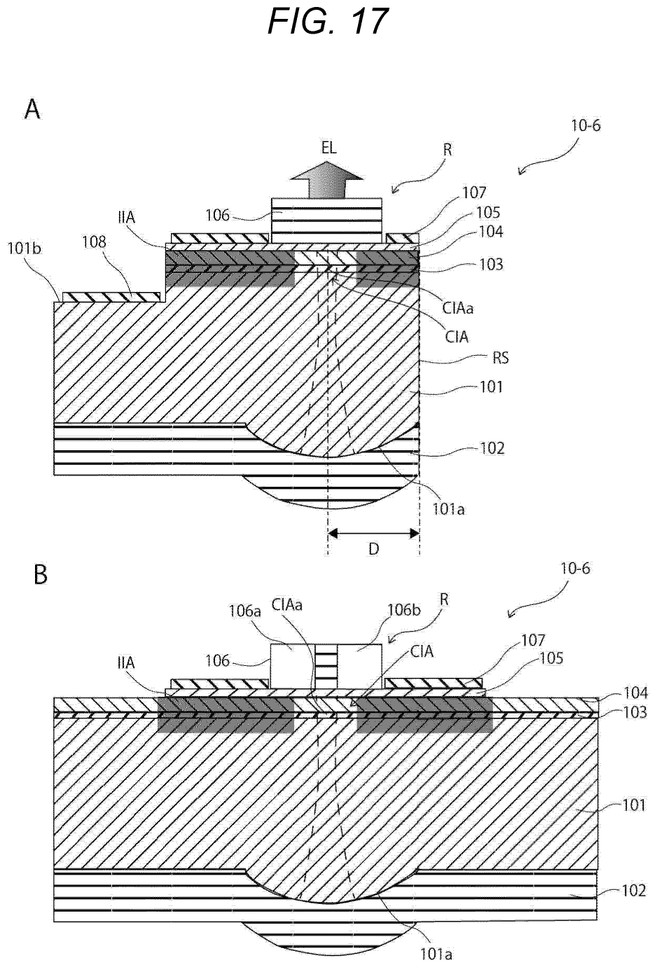

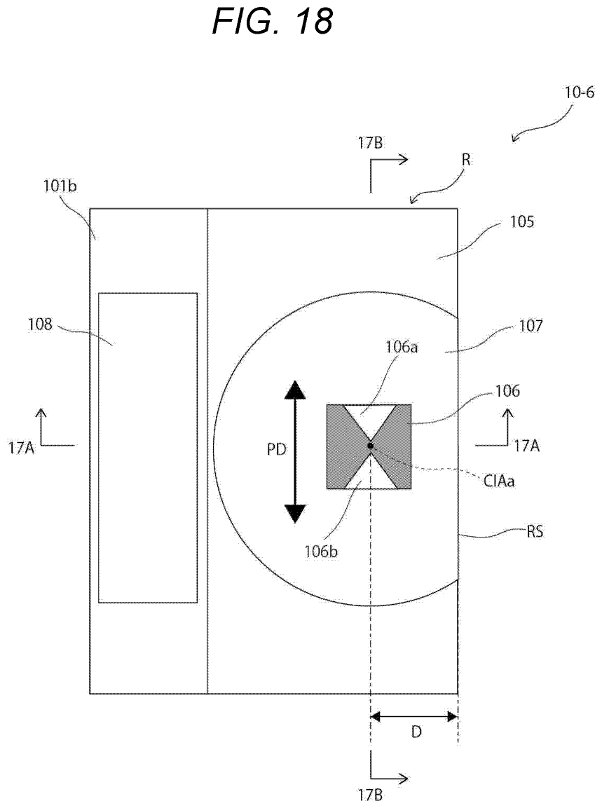

Hereinafter, a surface emitting laser according to Example 6 of one embodiment of the present technology will be described with reference to the drawings. FIG. 17A is a cross-sectional view (part 1) of a surface emitting laser 10-6 according to Example 6 of one embodiment of the present technology. FIG. 17B is a cross-sectional view (part 2) of the surface emitting laser 10-6 according to Example 6 of one embodiment of the present technology. FIG. 18 is a plan view of the surface emitting laser 10-6 according to Example 6 of one embodiment of the present technology. FIG. 17A is a cross-sectional view taken along line 17A-17A in FIG. 18. FIG. 17B is a cross-sectional view taken along line 17B-17B in FIG. 18.

Meanwhile, as a method of imparting distortion in one direction to the active layer, for example, residual stress at the time of forming a layer other than the active layer of the VCSEL can be used. In a case where the layer has an asymmetric shape (anisotropic shape), distortion is imparted to the active layer in one direction, and the polarization direction is controlled in one direction.

As illustrated in FIGS. 17A, 17B, and 18, the surface emitting laser 10-6 has a configuration similar to the surface emitting laser 10-1 according to Example 1 except that the second reflecting mirror 106 has an anisotropic shape (asymmetric shape).

In the surface emitting laser 10-6, the second reflecting mirror 106 has a pair of notch portions 106a and 106b facing each other in the 17B-17B line direction (see FIG. 18) with the center CIAa of the current injection region CIA interposed therebetween in plan view. Here, the pair of notch portions 106a and 106b has an equilateral triangular shape in plan view, and the vertices face each other so as to face each other.

The pair of notch portions 106a and 106b functions as a stress applying structure for applying a stress in the 17B-17B line direction to the active layer 103. The stress applying structure has a function of controlling the polarization direction to one polarization direction PD. The stress may be a tensile stress or a compressive Stress. The stress applying structure may be any other structure as long as a stress in one direction can be applied to the active layer 103.

According to the surface emitting laser 10-6, effects similar to those of the surface emitting laser 10-1 according to Example 1 can be obtained, and the polarization control function by the reflection surface RS and the polarization control function by the stress applying structure work synergistically, so that the polarization control function can be adjusted (enhanced).

Note that, as a polarization control method accompanying the polarization control function by the reflection surface RS, in addition to or instead of the polarization control function by the stress applying structure, a polarization control function of giving optical gain anisotropy to the active layer itself using an inclined substrate and a polarization control function of giving anisotropy to the resonator internal loss may be added. In addition, in place of or in addition to the second reflecting mirror 106, a stress applying structure may be provided in a component other than the second reflecting mirror 106 of the surface emitting laser 10-6.

### 7. Surface Emitting Laser According to Example 7 of One Embodiment of Present Technology

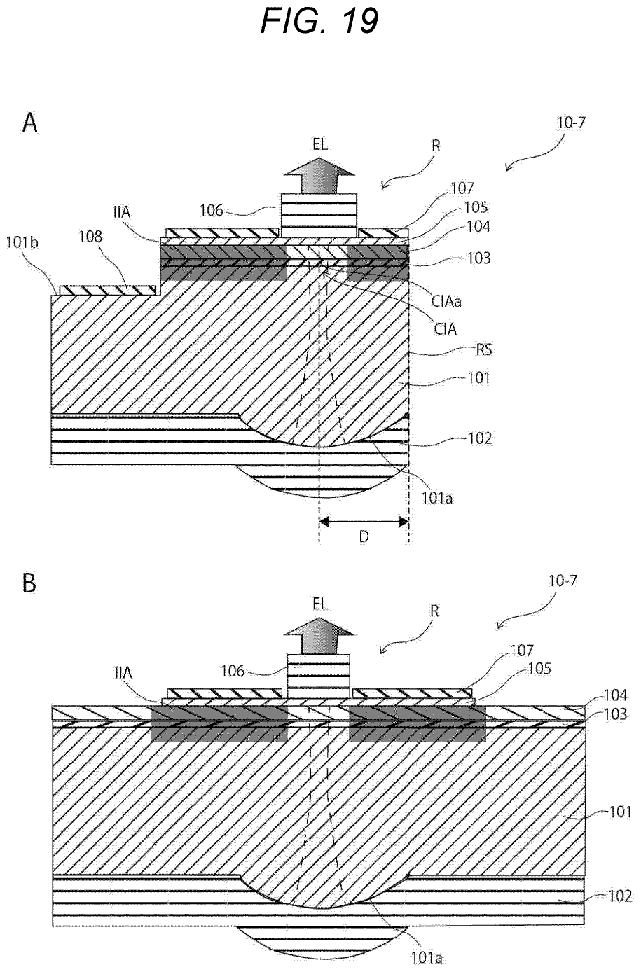

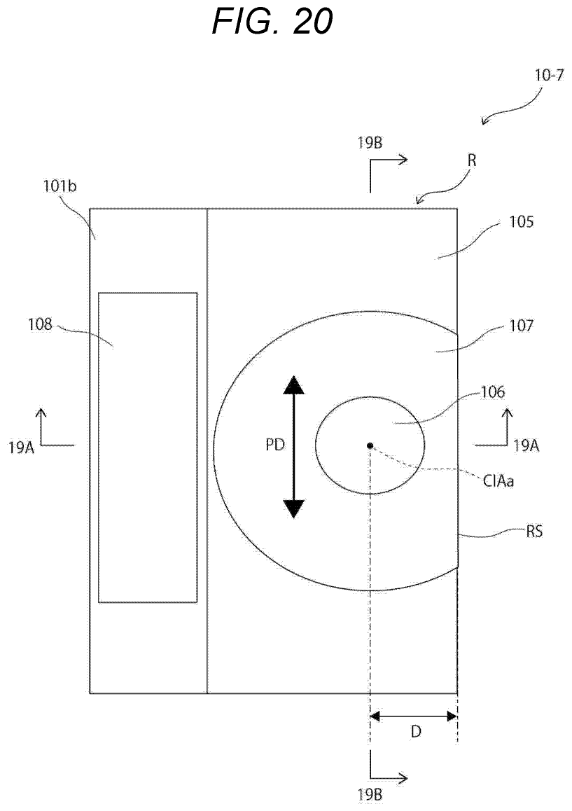

Hereinafter, a surface emitting laser according to Example 7 of one embodiment of the present technology will be described with reference to the drawings. FIG. 19A is a cross-sectional view (part 1) of a surface emitting laser 10-7 according to Example 7 of one embodiment of the present technology. FIG. 19B is a cross-sectional view (part 2) of the surface emitting laser 10-7 according to Example 7 of one embodiment of the present technology. FIG. 20 is a plan view of the surface emitting laser 10-7 according to Example 7 of one embodiment of the present technology. FIG. 19A is a cross-sectional view taken along line 19A-19A in FIG. 20. FIG. 19B is a cross-sectional view taken along line 19B-19B in FIG. 20.

As illustrated in FIGS. 19A, 19B, and 20, the surface emitting laser 10-7 has a configuration substantially similar to the surface emitting laser 10-1 according to Example 1 except that the inner edge of the anode electrode 107 has an anisotropic shape (asymmetric shape).

In the surface emitting laser 10-7, the inner edge of the anode electrode 107 has an elliptical shape with the 19A-19A line direction (see FIG. 20) as the major axis direction and the 19B-19B line direction (see FIG. 20) as the minor axis direction. The anode electrode 107 has a lateral mode control function of controlling the lateral mode to a desired single lateral mode by giving anisotropy to the loss of the lateral mode. As an example, the inner edge of the anode electrode 107 is located near the outer edge of the current injection region CIA in plan view.

According to the surface emitting laser 10-7, effects similar to those of the surface emitting laser 10-1 according to Example 1 can be obtained, and a polarization control function by the reflection surface RS and a lateral mode control function by the anode electrode 107 are provided, so that it is possible to emit light in a single lateral mode in which the polarization direction is controlled to one polarization direction PD.

Note that, in place of or in addition to the second reflecting mirror 106, components of the surface emitting laser 10-6 other than the second reflecting mirror 106 may have a similar lateral mode control function.

### 8. Surface Emitting Laser According to Example 8 of One Embodiment of Present Technology

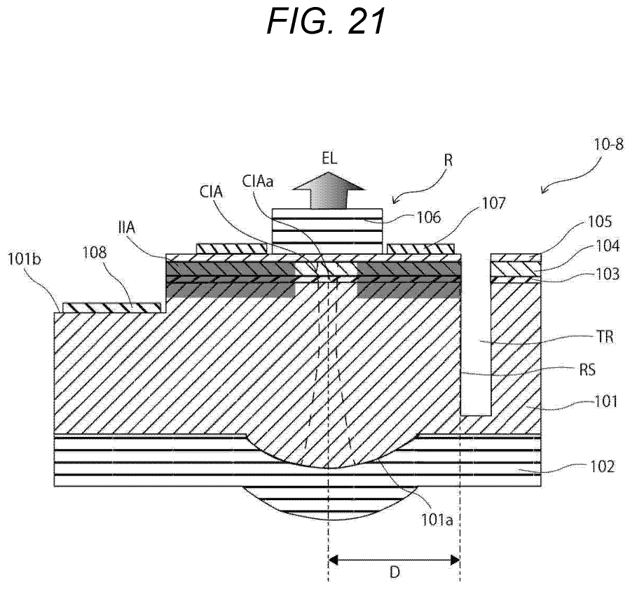

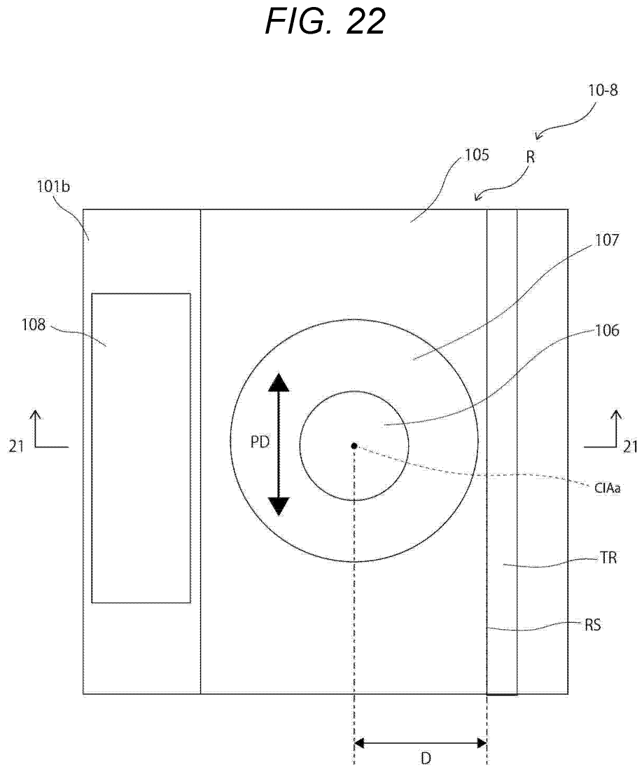

Hereinafter, a surface emitting laser according to Example 8 of one embodiment of the present technology will be described with reference to the drawings. FIG. 21 is a cross-sectional view of a surface emitting laser 10-8 according to Example 8 of one embodiment of the present technology. FIG. 22 is a plan view of the surface emitting laser 10-8 according to Example 8 of one embodiment of the present technology. FIG. 21 is a cross-sectional view taken along line 21-21 in FIG. 22.

### Configuration of Surface Emitting Laser

As illustrated in FIGS. 21 and 22, the surface emitting laser 10-8 has a configuration similar to the surface emitting laser 10-1 according to Example 1 except that the reflection surface RS is at least a part (all or a part) of a side surface of a trench TR (groove) provided in the resonator R.

The trench TR is a groove located outside the current injection region CIA in plan view, and is a groove whose length direction is a horizontal direction orthogonal to the 21-21 line direction (see FIG. 22) and whose depth direction is a vertical direction (emission direction). The bottom surface of the trench TR is located in the lower half portion of the substrate 101 and is opened by at least the transparent conductive film 105. The depth of the trench TR is preferably 25% or more of the thickness of the resonator R. The trench TR has a pair of side surfaces facing each other in the 21-21 line direction (see FIG. 22), and a side surface closer to the current injection region CIA among the pair of side surfaces is the reflection surface RS. That is, the reflection surface RS includes an interface between the semiconductor and air.

### Method for Manufacturing Surface Emitting Laser

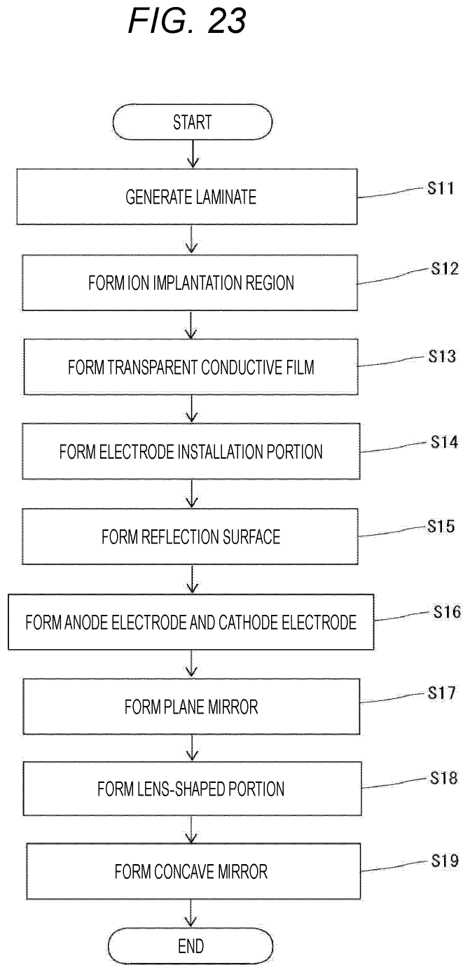

Hereinafter, an example of a method for manufacturing the surface emitting laser 10-8 will be described with reference to a flowchart of FIG. 23 and the like.

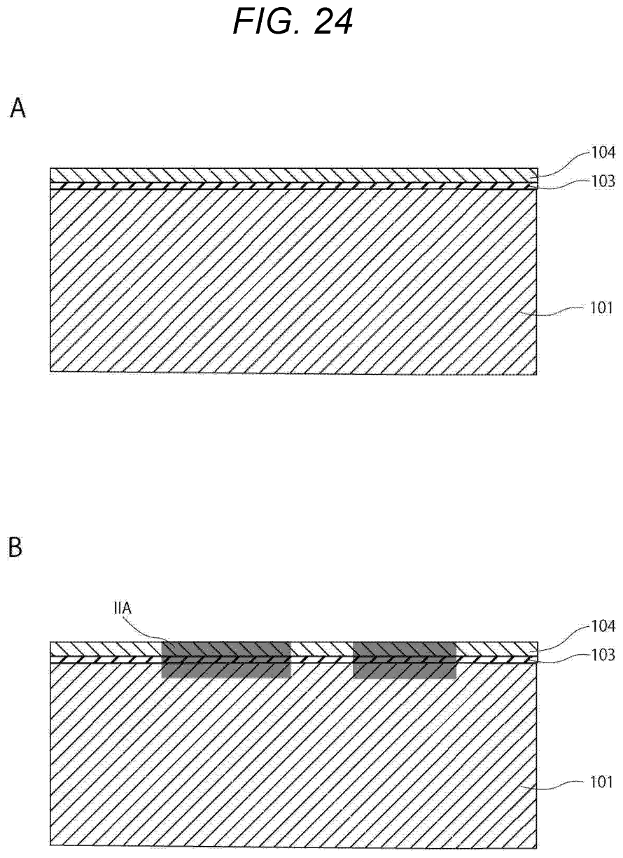

In the first step S11, a laminate is generated (see FIG. 24A). Specifically, the active layer 103 and the cladding layer 104 are grown in this order on the substrate 101 (for example, n-GaN substrate) in a growth chamber by a metal organic chemical vapor deposition method (MOCVD method) or a molecular beam epitaxy method (MBE method) to generate a laminate.

In the next step S12, the ion implantation region IIA is formed (see FIG. 24B). Specifically, a protective film constituted by resist, SiO₂, or the like is formed to cover a portion other than the portion where the ion implantation region IIA is formed on the laminate, and ions (for example, B⁺⁺) are implanted into the laminate from the cladding layer 104 side using the protective film as a mask. At this time, it is assumed that the implantation depth of the ion implantation reaches the inside of the substrate 101.

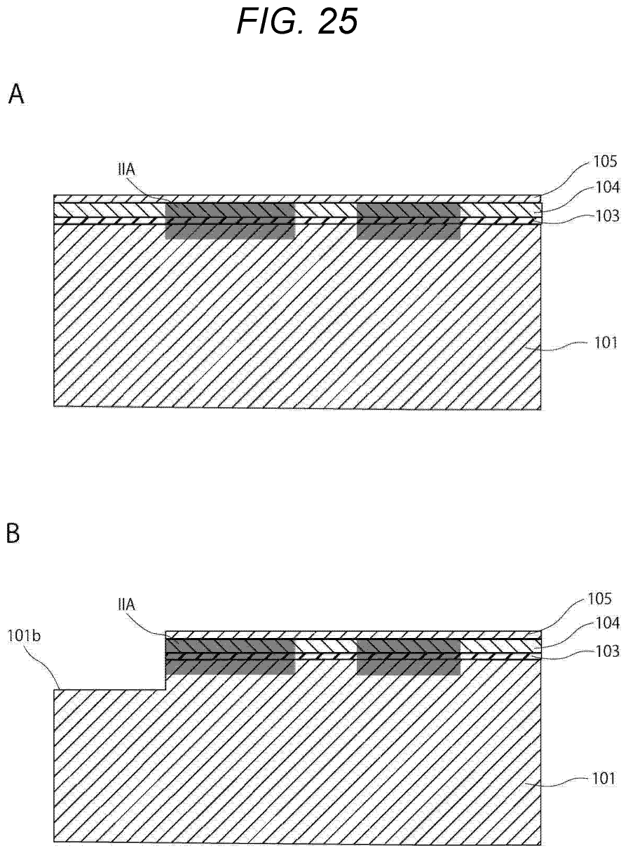

In the next step S13, the transparent conductive film 105 is formed (see FIG. 25A). Specifically, first, the transparent conductive film 105 is formed on the entire surface by, for example, a vacuum vapor deposition method, sputtering, or the like.

In the next step S14, the electrode installation portion 101b is formed (see FIG. 25B). Specifically, a resist pattern covering a portion other than the portion where the electrode installation portion 101b is formed on the laminate is formed, and the laminate is etched using the resist pattern as a mask. At this time, etching is performed until the etching bottom surface is positioned in the substrate 101. As a result, a stepped portion having the electrode installation portion 101b as a bottom surface is formed on the laminate.

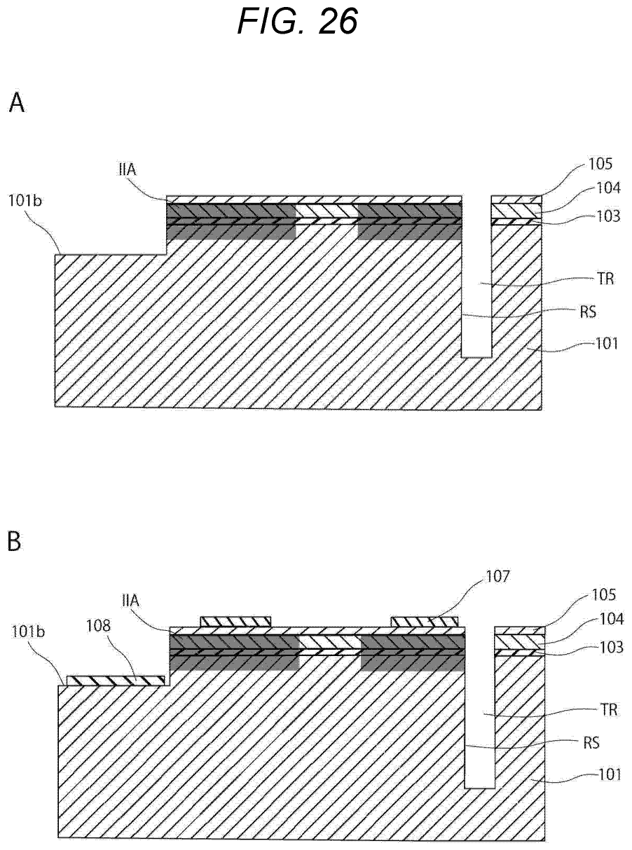

In the next step S15, the reflection surface RS is formed (see FIG. 26A). Specifically, a resist pattern covering a portion of the laminate other than a portion where the trench TR is formed is formed, and the laminate is etched using the resist pattern as a mask. At this time, etching is performed until the etching bottom surface is positioned in the lower half portion of the substrate 101. As a result, the trench TR having the reflection surface RS as one side surface is formed in the laminate.

In the next step S16, the anode electrode 107 and the cathode electrode 108 are formed (see FIG. 26B).

Specifically, for example, a lift-off method is used to form the anode electrode 107 in a circular shape on the transparent conductive film 105, and form the cathode electrode 108 on the electrode installation portion 101b. For the deposition of the electrode material at this time, for example, a vacuum vapor deposition method, sputtering, or the like is used.

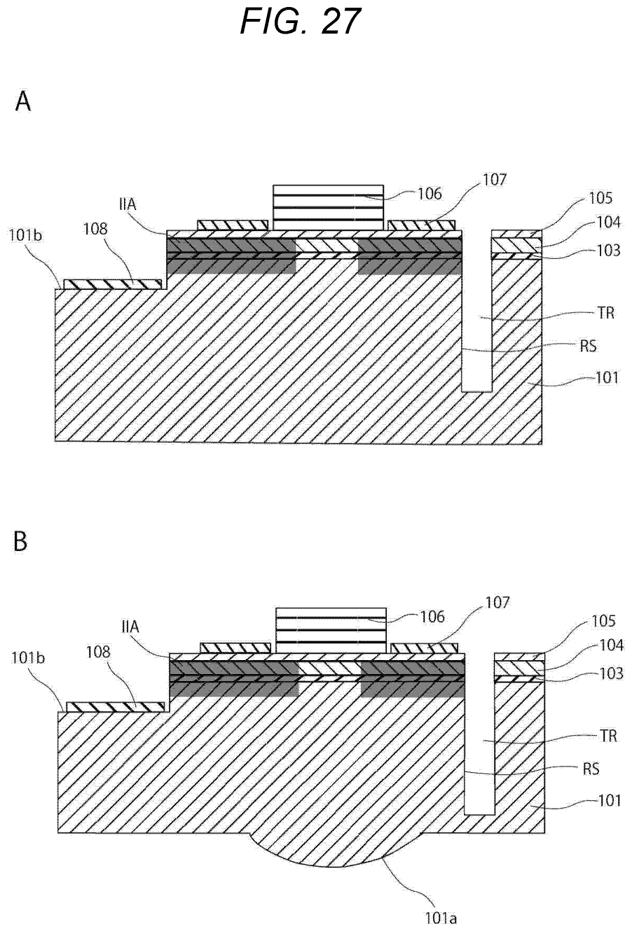

In the next step S17, a plane mirror as the second reflecting mirror 106 is formed (see FIG. 27A). Specifically, first, a dielectric multilayer film as a material of the second reflecting mirror 106 is formed on the entire surface by, for example, a vacuum vapor deposition method, a sputtering method, a CVD method, or the like. Next, a resist pattern covering only the dielectric multilayer film to be the second reflecting mirror 106 is formed, and etching is performed using the resist pattern as a mask to leave only the dielectric multilayer film to be the second reflecting mirror 106.

In the next step S18, the lens-shaped portion 101a is formed (see FIG. 27B). Specifically, first, a resist is formed at a portion where the lens-shaped portion 101a is to be formed on the back surface of the substrate 101 by photolithography. Next, for example, the resist is formed into a lens shape (for example, a substantially hemispherical shape) by reflow at a temperature of 200 °C. Next, etching is performed using a resist as a mask to form the lens-shaped portion 101a in, for example, a substantially hemispherical shape.

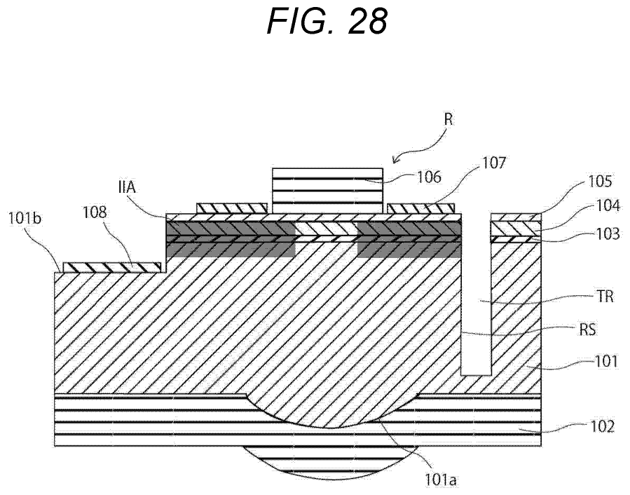

In the final step S19, a concave mirror as the first reflecting mirror 102 is formed (see FIG. 28).

Specifically, the material of the first reflecting mirror 102 (for example, a dielectric multilayer film) is formed on the back surface of the substrate 101 on which the lens-shaped portion 101a is formed by, for example, a vacuum vapor deposition method, a sputtering method, a CVD method, or the like. As a result, a concave mirror having a shape following the lens-shaped portion 101a is formed.

The surface emitting laser 10-8 generated as described above is mounted on, for example, a CAN package. More specifically, the surface of the surface emitting laser 10-8 on the first reflecting mirror 102 side is soldered to the CAN package.

### Effects of Surface Emitting Laser

According to the surface emitting laser 10-8, effects similar to those of the surface emitting laser 10-1 according to Example 1 can be obtained.

### 9. Surface Emitting Laser According to Example 9 of One Embodiment of Present Technology

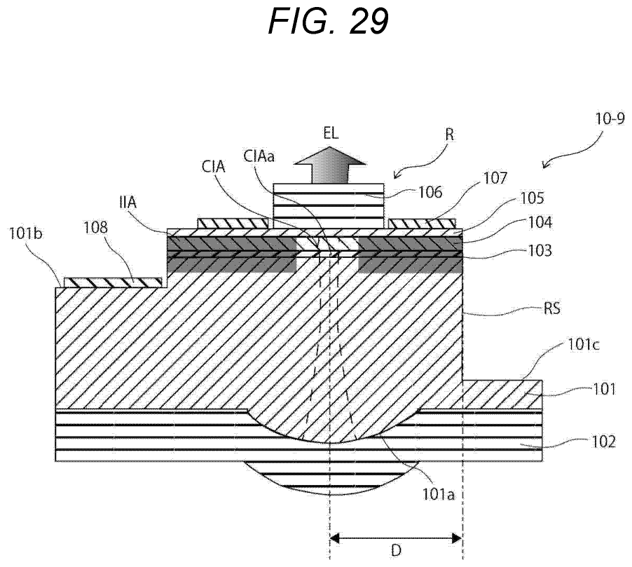

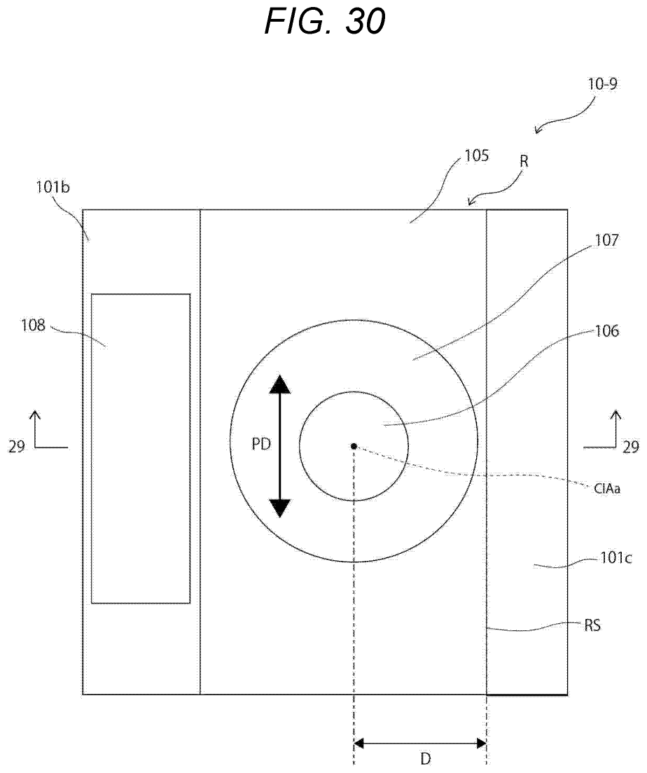

Hereinafter, a surface emitting laser according to Example 9 of one embodiment of the present technology will be described with reference to the drawings. FIG. 29 is a cross-sectional view of a surface emitting laser 10-9 according to Example 9 of one embodiment of the present technology. FIG. 30 is a plan view of the surface emitting laser 10-9 according to Example 9 of one embodiment of the present technology. FIG. 29 is a cross-sectional view taken along line 29-29 in FIG. 30.

### Configuration of Surface Emitting Laser

As illustrated in FIGS. 29 and 30, the surface emitting laser 10-9 has a configuration similar to the surface emitting laser 10-1 according to Example 1 except that the reflection surface RS is at least a part (all or part) of the side surface of the notch 101c provided in the resonator R.

The notch 101c is a notch located outside the current injection region CIA in plan view, extends in the horizontal direction orthogonal to the 29-29 line direction (see FIG. 30), and has the vertical direction (emission direction) as the height direction (see FIG. 29). The notch 101c has a bottom surface located in the substrate 101. The height of the notch 101c is preferably 25% or more of the thickness of the resonator R. The reflection surface RS, which is a side surface of the notch 101c, includes an interface between a semiconductor and air.

### Method for Manufacturing Surface Emitting Laser

Hereinafter, an example of a method for manufacturing the surface emitting laser 10-9 will be described with reference to the drawings.

In the first step, a laminate is generated (see FIG. 24A). Specifically, the active layer 103 and the cladding layer 104 are grown in this order on the substrate 101 (for example, n-GaN substrate) in a growth chamber by a metal organic chemical vapor deposition method (MOCVD method) or a molecular beam epitaxy method (MBE method) to generate a laminate.

In the second step, the ion implantation region IIA is formed (see FIG. 24B). Specifically, a protective film constituted by resist, SiO₂, or the like is formed to cover a portion other than the portion where the ion implantation region IIA is formed on the laminate, and ions (for example, B⁺⁺) are implanted into the laminate from the cladding layer 104 side using the protective film as a mask. At this time, it is assumed that the implantation depth of the ion implantation reaches the inside of the substrate 101.

In the third step, the transparent conductive film 105 is formed (see FIG. 25A). Specifically, first, the transparent conductive film 105 is formed on the entire surface by, for example, a vacuum vapor deposition method, sputtering, or the like.

In the fourth step, the electrode installation portion 101b is formed (see FIG. 25B). Specifically, a resist pattern covering a portion other than the portion where the electrode installation portion 101b is formed on the laminate is formed, and the laminate is etched using the resist pattern as a mask. At this time, etching is performed until the etching bottom surface is positioned in the substrate 101. As a result, a stepped portion having the electrode installation portion 101b as a bottom surface is formed on the laminate.

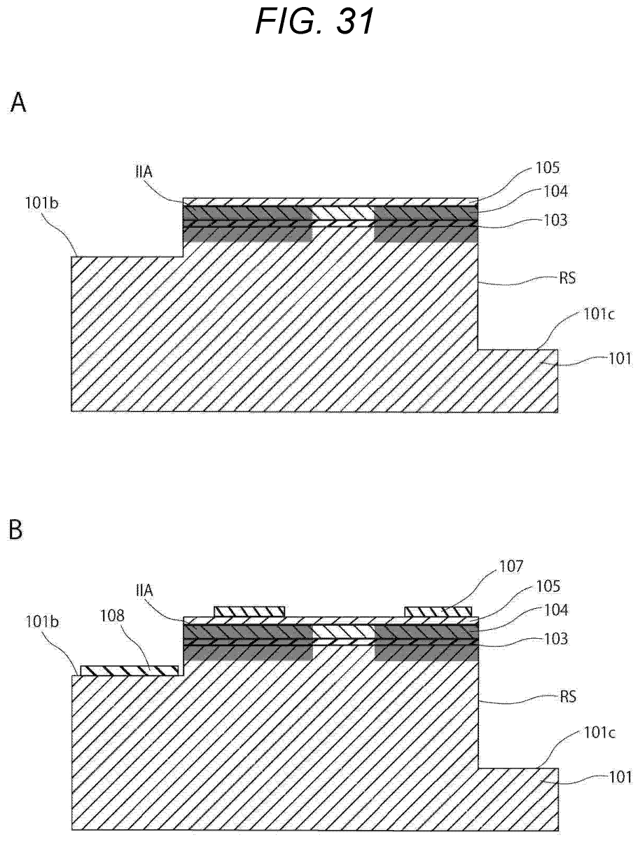

In the fifth step, the reflection surface RS is formed (see FIG. 31A). Specifically, a resist pattern covering a portion of the laminate other than a portion where the notch 101c is formed is formed, and the laminate is etched using the resist pattern as a mask. At this time, etching is performed until the etching bottom surface is positioned in the lower half portion of the substrate 101. As a result, the notch 101c having the reflection surface RS as a side surface is formed in the laminate.

In the sixth step, the anode electrode 107 and the cathode electrode 108 are formed (see FIG. 31B). Specifically, for example, a lift-off method is used to form the anode electrode 107 in a circular shape on the transparent conductive film 105, and form the cathode electrode 108 on the electrode installation portion 101b. For the deposition of the electrode material at this time, for example, a vacuum vapor deposition method, sputtering, or the like is used.

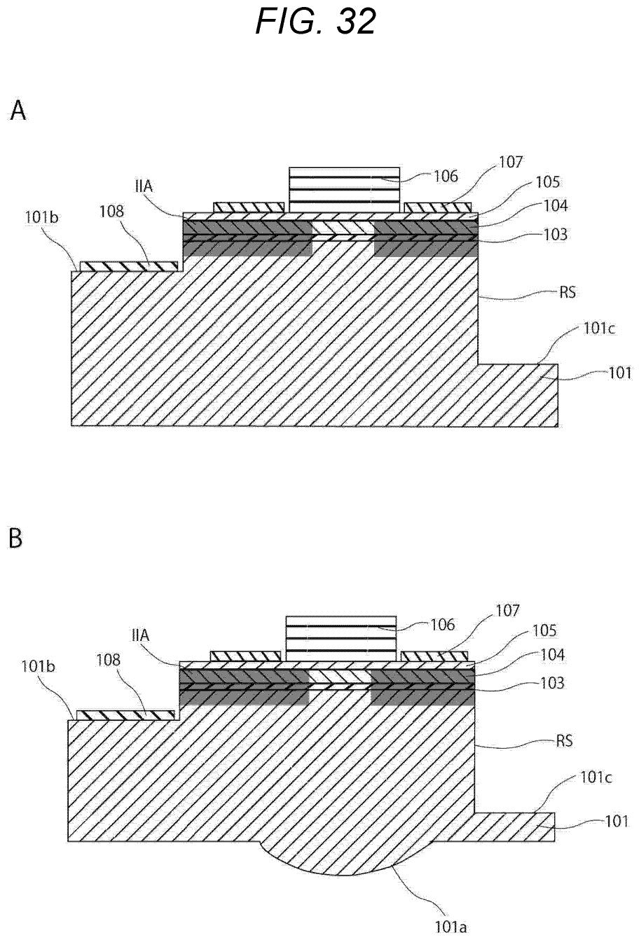

In the seventh step, a plane mirror as the second reflecting mirror 106 is formed (see FIG. 32A).

Specifically, first, a dielectric multilayer film as a material of the second reflecting mirror 106 is formed on the entire surface by, for example, a vacuum vapor deposition method, a sputtering method, a CVD method, or the like. Next, a resist pattern covering only the dielectric multilayer film to be the second reflecting mirror 106 is formed, and etching is performed using the resist pattern as a mask to leave only the dielectric multilayer film to be the second reflecting mirror 106.

In the eighth step, the lens-shaped portion 101a is formed (see FIG. 32B). Specifically, first, a resist is formed at a portion where the lens-shaped portion 101a is to be formed on the back surface of the substrate 101 by photolithography. Next, for example, the resist is formed into a lens shape (for example, a substantially hemispherical shape) by reflow at a temperature of 200 °C. Next, etching is performed using a resist as a mask to form the lens-shaped portion 101a in, for example, a substantially hemispherical shape.

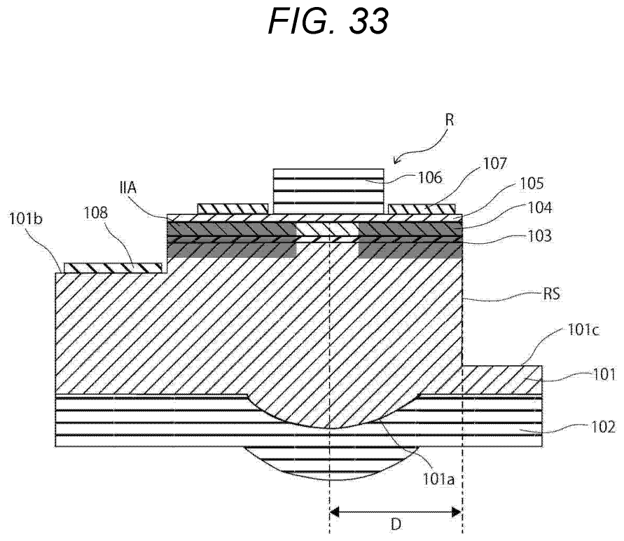

In the ninth step, a concave mirror as the first reflecting mirror 102 is formed (see FIG. 33). Specifically, the material of the first reflecting mirror 102 (for example, a dielectric multilayer film) is formed on the back surface of the substrate 101 on which the lens-shaped portion 101a is formed by, for example, a vacuum vapor deposition method, a sputtering method, a CVD method, or the like. As a result, a concave mirror having a shape following the lens-shaped portion 101a is formed.

The surface emitting laser 10-9 generated as described above is mounted on, for example, a CAN package. More specifically, the surface of the surface emitting laser 10-9 on the first reflecting mirror 102 side is soldered to the CAN package.

### Effects of Surface Emitting Laser

According to the surface emitting laser 10-9, effects similar to those of the surface emitting laser 10-1 according to Example 1 can be obtained.

### 10. Surface Emitting Laser According to Example 10 of One Embodiment of Present Technology

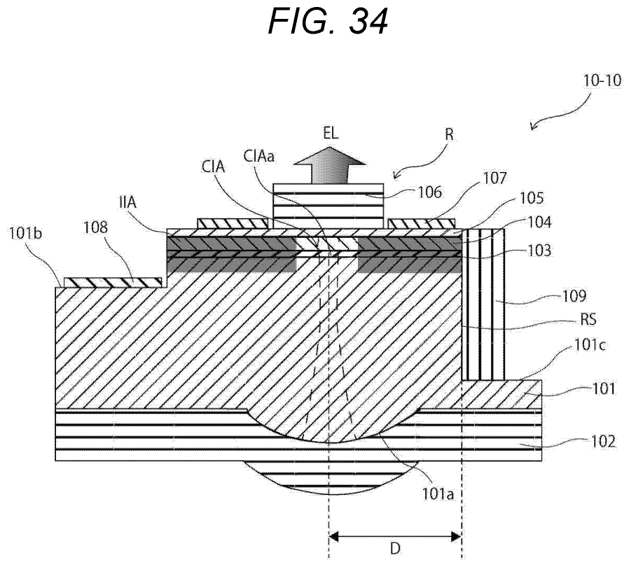

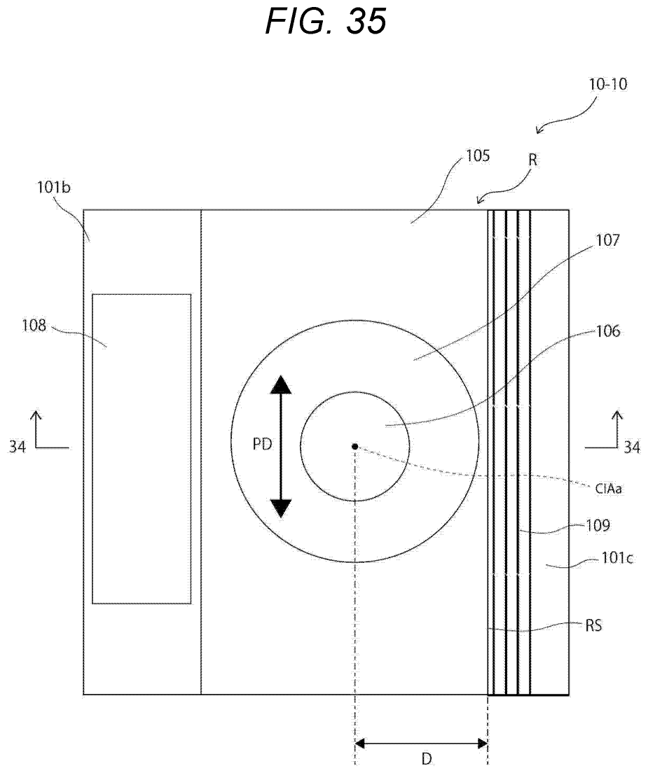

Hereinafter, a surface emitting laser according to Example 10 of one embodiment of the present technology will be described with reference to the drawings. FIG. 34 is a cross-sectional view of a surface emitting laser 10-10 according to Example 10 of one embodiment of the present technology. FIG. 35 is a plan view of the surface emitting laser 10-10 according to Example 10 of one embodiment of the present technology. FIG. 34 is a cross-sectional view taken along line 34-34 in FIG. 35.

As illustrated in FIGS. 34 and 35, the surface emitting laser 10-10 has a configuration similar to the surface emitting laser 10-9 according to Example 9 except that the reflection portion includes a multilayer film reflecting mirror 109 as a reflecting structure in addition to the reflection surface RS.

The multilayer film reflecting mirror 109 is provided on at least a part (for example, all) of the reflection surface RS. The multilayer film reflecting mirror 109 is, for example, a semiconductor multilayer film reflecting mirror, a dielectric multilayer film reflecting mirror, or the like. The multilayer film reflecting mirror 109 has a laminated structure in which a high refractive index layer and a low refractive index layer are alternately laminated in the horizontal direction (specifically, the 34-34 line direction in FIG. 35) at an optical thickness of λ/4.

The reflectance of the reflection portion including the reflection surface RS and the multilayer film reflecting mirror 109 is, for example, preferably 10% or more, more preferably 20% or more, still more preferably 30% or more, still more preferably 40% or more, and still more sufficiently preferably 50% or more.

According to the surface emitting laser 10-10, effects similar to those of the surface emitting laser 10-9 according to Example 9 can be obtained, and since the reflection portion includes the multilayer film reflecting mirror 109 in addition to the reflection surface RS, the reflectance of the reflection portion can be adjusted. To supplement, in the surface emitting laser 10-10, even if the reflectance of the reflection surface RS is low, the reflectance of the entire reflection portion can be increased.

### 11. Surface Emitting Laser According to Example 11 of One Embodiment of Present Technology

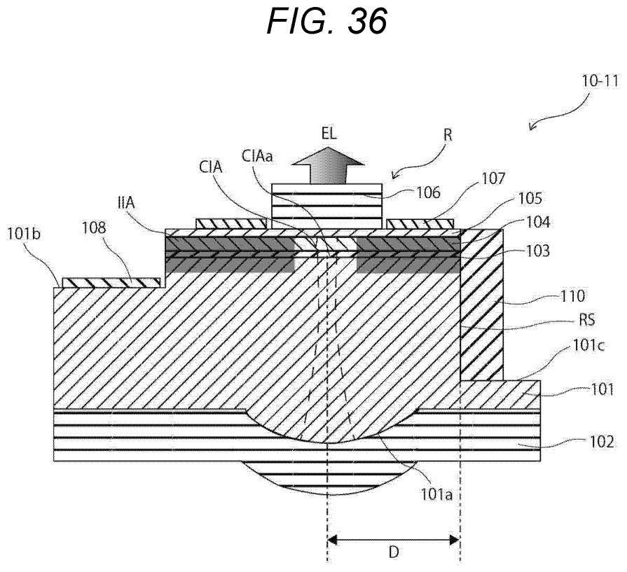

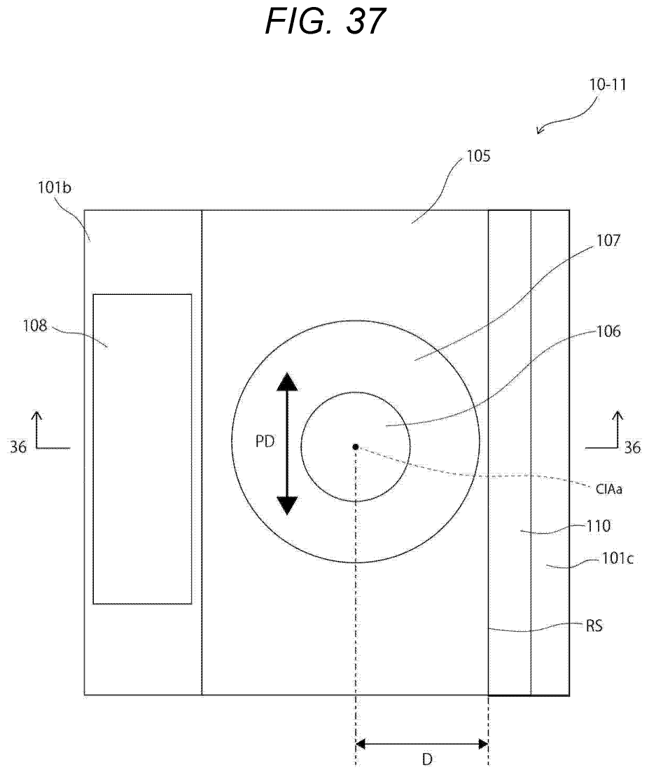

Hereinafter, a surface emitting laser according to Example 11 of one embodiment of the present technology will be described with reference to the drawings. FIG. 36 is a cross-sectional view of a surface emitting laser 10-11 according to Example 11 of one embodiment of the present technology. FIG. 37 is a plan view of the surface emitting laser 10-11 according to Example 11 of one embodiment of the present technology. FIG. 36 is a cross-sectional view taken along line 36-36 in FIG. 37.

As illustrated in FIGS. 36 and 37, the surface emitting laser 10-11 has a configuration similar to the surface emitting laser 10-9 according to Example 9 except that the reflection portion has a reflective film 110 as a reflecting structure in addition to the reflection surface RS.

The reflective film 110 is provided on at least a part (for example, all) of the reflection surface RS. The reflective film 110 is, for example, a metal film or a dielectric film. The reflective film 110 may have a single-layer structure or a multilayer structure with a horizontal direction (specifically, a 36-36 line direction in FIG. 37) as a laminating direction.

The reflectance of the reflection portion including the reflection surface RS and the reflective film 110 is, for example, preferably 10% or more, more preferably 20% or more, still more preferably 30% or more, still more preferably 40% or more, and still more sufficiently preferably 50% or more.

According to the surface emitting laser 10-11, effects similar to those of the surface emitting laser 10-9 according to Example 9 can be obtained, and since the reflection portion has the reflective film 110 in addition to the reflection surface RS, the reflectance of the reflection portion can be adjusted. To supplement, in the surface emitting laser 10-11, even if the reflectance of the reflection surface RS is low, the reflectance of the entire reflection portion can be increased.

### 12. Surface Emitting Laser According to Example 12 of One Embodiment of Present Technology

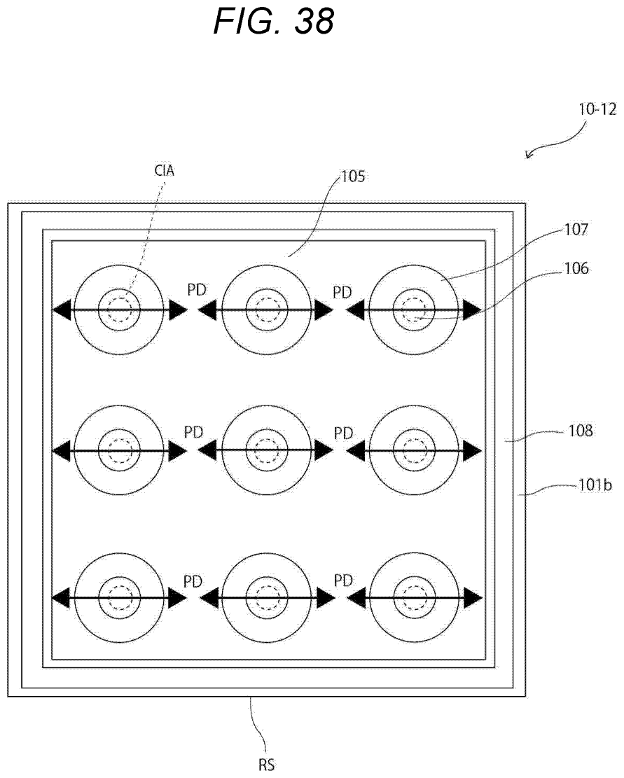

Hereinafter, a surface emitting laser according to Example 12 of one embodiment of the present technology will be described with reference to the drawings. FIG. 38 is a plan view of the surface emitting laser 10-12 according to Example 12 of one embodiment of the present technology.

As illustrated in FIG. 38, in the surface emitting laser 10-12, the active layer 103 has a plurality of (for example, nine) current injection regions CIA, and the reflection surface RS is provided in common to the plurality of current injection regions CIA.

In the surface emitting laser 10-12, a plurality of (for example, nine) current confinement regions for setting the current injection region CIA of the active layer 103 is provided in an array (for example, a matrix). That is, in the surface emitting laser 10-12, there is a plurality of current injection regions CIA arranged in an array (for example, a matrix). The surface emitting laser 10-12 constitutes a surface emitting laser array in which a plurality of (for example, nine) light emitting sections including the current injection region CIA is arranged in an array.

Each of the light emitting sections has a cross-sectional configuration similar to that of the surface emitting laser according to any other examples in which the cross-sectional configuration is illustrated.

Here, the electrode installation portion 101b is formed in a frame shape so as to surround the plurality of light emitting sections, and the frame-shaped cathode electrode 108 is provided on the electrode installation portion 101b.

The polarization direction of each light emitting section is controlled to one polarization direction PD by optical confinement in the lateral direction by the reflection surface RS.

According to the surface emitting laser 10-12, the polarization directions of the light emitting sections can be aligned with one polarization direction PD. As a result, coherence of light emitted from the plurality of light emitting sections is improved. Therefore, the radiation angle of the emitted light (far field pattern: FFP) can be reduced when the plurality of light emitting sections is simultaneously driven.

In the surface emitting laser 10-12, the multilayer film reflecting mirror 109 or the reflective film 110 may be provided on the reflection surface RS.

### 13. Surface Emitting Laser According to Example 13 of One Embodiment of Present Technology

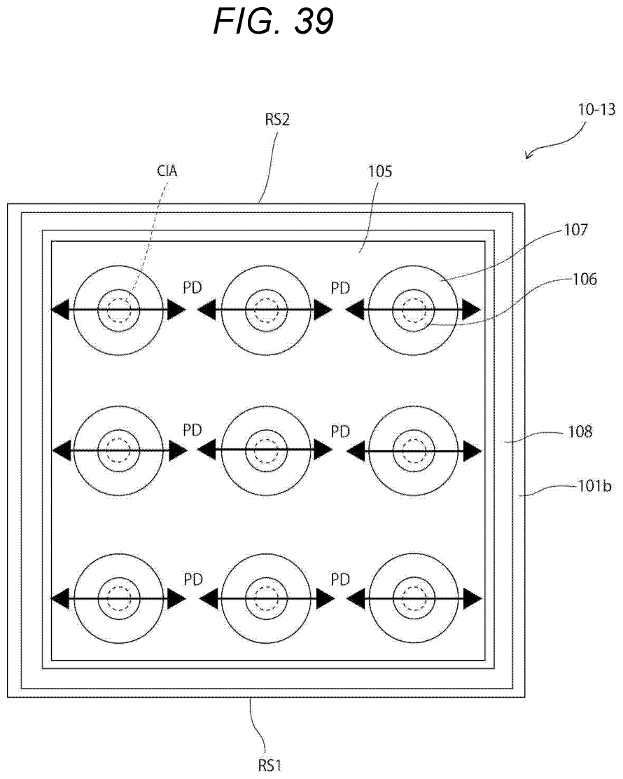

Hereinafter, a surface emitting laser according to Example 13 of one embodiment of the present technology will be described with reference to the drawings. FIG. 39 is a plan view of the surface emitting laser 10-13 according to Example 13 of one embodiment of the present technology.

As illustrated in FIG. 39, in the surface emitting laser 10-13, the active layer 103 has a plurality of (for example, nine) current injection regions CIA, and a plurality of (for example, two) reflection surfaces (for example, the first and second reflection surfaces RS1 and RS2) is provided in common in the plurality of current injection regions CIA.

In the surface emitting laser 10-13, a plurality of (for example, nine) current confinement regions for setting the current injection region CIA of the active layer 103 is provided in an array (for example, a matrix). That is, in the surface emitting laser 10-13, there is a plurality of current injection regions CIA arranged in an array (for example, a matrix). The surface emitting laser 10-13 constitutes a surface emitting laser array in which a plurality of (for example, nine) light emitting sections including the current injection region CIA is arranged in an array.

Each of the light emitting sections has a cross-sectional configuration similar to that of the surface emitting laser according to any other examples in which the cross-sectional configuration is illustrated.

Here, the electrode installation portion 101b is formed in a frame shape so as to surround the plurality of light emitting sections, and the frame-shaped cathode electrode 108 is provided on the electrode installation portion 101b.

In the plurality of current injection regions CIA, the polarization direction is controlled to one polarization direction PCD by optical confinement in the lateral direction of each of the first and second reflection surfaces RS1 and RS2.

According to the surface emitting laser 10-13, it is possible to provide a surface emitting laser array in which the polarization directions of the light emitting sections are more reliably aligned in one polarization direction PD.

In the surface emitting laser 10-13, the multilayer film reflecting mirror 109 or the reflective film 110 may be provided on at least one of the first or second reflection surfaces RS1 or RS2.

### 14. Surface Emitting Laser According to Example 14 of One Embodiment of Present Technology

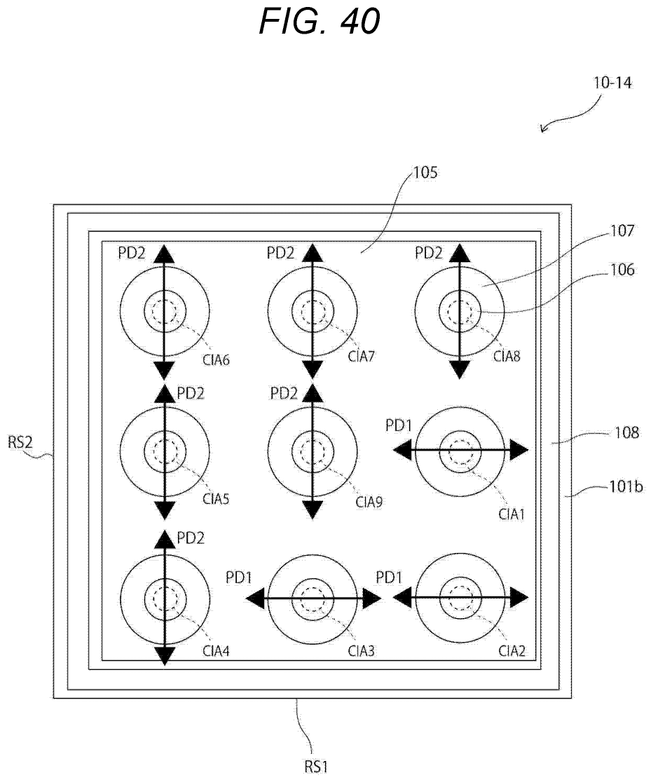

Hereinafter, a surface emitting laser according to Example 14 of one embodiment of the present technology will be described with reference to the drawings. FIG. 40 is a plan view of the surface emitting laser 10-14 according to Example 14 of one embodiment of the present technology.

In the surface emitting laser 10-14, the active layer 103 has a plurality of (for example, nine) current injection regions CIA, and the resonator R has a plurality of (for example, the first and second reflection surfaces RS1 and RS2) reflection surfaces.

Here, the first and second reflection surfaces RS1 and RS2 are not parallel to each other. Specifically, the first and second reflection surfaces RS1 and RS2 are orthogonal to each other in plan view. Note that the present invention is not limited thereto, and in plan view, the first reflection surface RS1 or a virtual plane including the first reflection surface RS and the second reflection surface RS or a virtual plane including the second reflection surface RS2 may intersect each other at an angle other than 90°.

In the surface emitting laser 10-14, a plurality of (for example, nine) current confinement regions for setting the current injection region CIA of the active layer 103 is provided in an array (for example, a matrix). That is, in the surface emitting laser 10-14, there is a plurality of (for example, nine) current injection regions CIA arranged in an array (for example, in a matrix). The surface emitting laser 10-13 constitutes a surface emitting laser array in which a plurality of (for example, nine) light emitting sections including the current injection region CIA is arranged in an array.

Each of the light emitting sections has a cross-sectional configuration similar to that of the surface emitting laser according to any other examples in which the cross-sectional configuration is illustrated.

In the surface emitting laser 10-14, the first reflection surface RS1 (some reflection surfaces) among the plurality of reflection surfaces is provided in common to some (for example, three) current injection regions CIA (for example, the current injection regions CIA1, CIA2, and CIA3) among the plurality of current injection regions CIA, and the second reflection surface RS2 (the other reflection surfaces) among the plurality of reflection surfaces is provided in common to the other (for example, six) current injection regions CIA (CIA4, CIA5, CIA6, CIA7, CIA8, and CIA9) among the plurality of current injection regions CIA.

Here, as described above, the magnitude of optical confinement in the lateral direction with respect to each light emitting section by each reflection surface depends on the distance between the reflection surface and the light emitting section and the reflectance of the reflection surface.

In the surface emitting laser 10-14, the distance between each reflection surface and each current injection region and the reflectance of the reflection surface are set such that the optical confinement in the lateral direction by the first reflection surface RS1 is dominant among the optical confinement in the lateral direction by the first and second reflection surfaces RS1 and RS2 with respect to the light emitted from each of the current injection regions CIA1, CIA2, and CIA3. As a result, the light emitted from each of the current injection regions CIA1, CIA2, and CIA3 is controlled in one polarization direction PD1, which is the horizontal direction parallel to the first reflection surface RS1.

In the surface emitting laser 10-14, the distance between each reflection surface and each current injection region and the reflectance of the reflection surface are set such that the optical confinement in the lateral direction by the second reflection surface RS2 becomes dominant in the optical confinement in the lateral direction by the first and second reflection surfaces RS1 and RS2 with respect to the light emitted from each of the current injection regions CIA4, CIA5, CIA6, CIA7, CIA8, and CIA9. As a result, the light emitted from each of the current injection regions CIA4, CIA5, CIA6, CIA7, CIA8, and CIA9 is controlled in one polarization direction PD2, which is a horizontal direction parallel to the second reflection surface RS2.

Here, the electrode installation portion 101b is formed in a frame shape so as to surround the plurality of light emitting sections, and the frame-shaped cathode electrode 108 is provided on the electrode installation portion 101b.

According to the surface emitting laser 10-14, it is possible to provide a surface emitting laser array capable of controlling the polarization directions of some light emitting sections and the polarization directions of the other light emitting sections among the plurality of light emitting sections arranged in an array to one polarization direction different from each other.

In the surface emitting laser 10-14, the multilayer film reflecting mirror 109 or the reflective film 110 may be provided on at least one of the first or second reflection surfaces RS1 or RS2.

Although the matrix arrangement has been described as an example of the array arrangement of the surface emitting lasers 10 to 12 to 10-14 according to Example 12 to 14, for example, another arrangement such as a staggered arrangement may be used.

### 15. Surface Emitting Laser According to Example 15 of One Embodiment of Present Technology

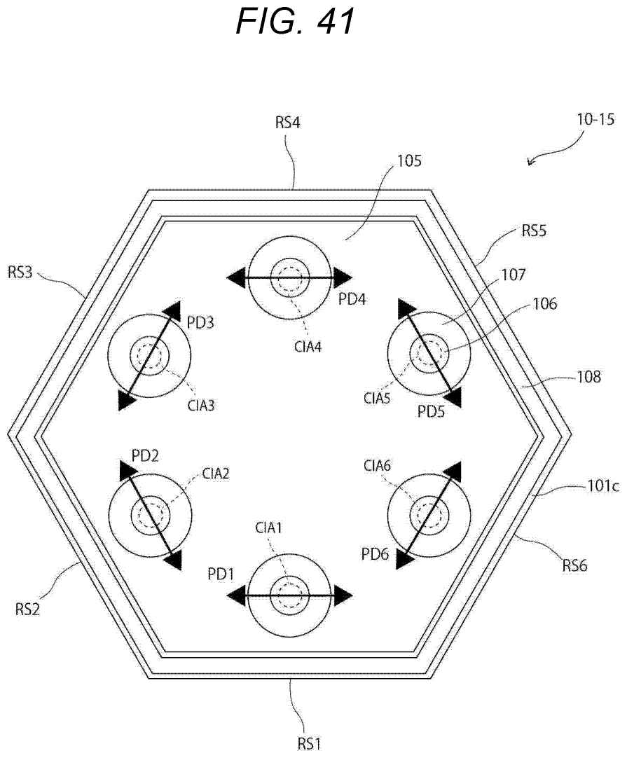

Hereinafter, a surface emitting laser according to Example 15 of one embodiment of the present technology will be described with reference to the drawings. FIG. 41 is a plan view of the surface emitting laser 10-15 according to Example 15 of one embodiment of the present technology.

In the surface emitting laser 10-15, the active layer 103 has a plurality of (for example, six) current injection regions CIA, and a plurality of (for example, six) reflection surfaces is provided.

In the surface emitting laser 10-15, a plurality of (for example, six) reflection surfaces (for example, reflection surfaces RS1 to RS6) is provided individually corresponding to a plurality of (for example, six) current injection regions CIA (for example, CIA1 to CIA6).

In the surface emitting laser 10-15, a plurality of (for example, six) current confinement regions for setting the current injection region CIA of the active layer 103 is provided in a circular shape. That is, in the surface emitting laser 10-15, there is a plurality of (for example, six) current injection regions CIA arranged in a circling manner. The surface emitting laser 10-15 constitutes a surface emitting laser array in which a plurality of (for example, six) light emitting sections including the current injection region CIA is arranged in a circling manner. Here, a plurality of (for example, six) current injection regions CIA is arranged at the vertices of the regular hexagon, but the present invention is not limited thereto, and it is sufficient that the plurality of current injection regions CIA is arranged at the vertices of the polygon.

In the surface emitting laser 10-15, the distance between each reflection surface and each current injection region and the reflectance of the reflection surface are set such that optical confinement in the lateral direction by the corresponding reflection surface becomes dominant with respect to light emitted from each current injection region. As a result, the light emitted from each current injection region is controlled in one polarization direction, which is a horizontal direction in which the polarization direction is parallel to the corresponding reflection surface.

Specifically, the light emitted from the current injection region CIA1 is controlled in one polarization direction PD1 in which the polarization direction is a horizontal direction parallel to the corresponding reflection surface RS1. The light emitted from the current injection region CIA2 is controlled in one polarization direction PD2 which is a horizontal direction parallel to the corresponding reflection surface RS2. The light emitted from the current injection region CIA3 is controlled in one polarization direction PD3 which is a horizontal direction parallel to the corresponding reflection surface RS3. The light emitted from the current injection region CIA4 is controlled in one polarization direction PD4 which is a horizontal direction parallel to the corresponding reflection surface RS4. The light emitted from the current injection region CIA5 is controlled in one polarization direction PD5 which is a horizontal direction parallel to the corresponding reflection surface RS5. The light emitted from the current injection region CIA6 is controlled in one polarization direction PD6 which is a horizontal direction parallel to the corresponding reflection surface RS6.

Each of the light emitting sections has a cross-sectional configuration similar to that of the surface emitting laser according to any other examples in which the cross-sectional configuration is illustrated.

Here, the electrode installation portion 101b is formed in a frame shape so as to surround the plurality of light emitting sections, and the frame-shaped cathode electrode 108 is provided on the electrode installation portion 101b.

According to the surface emitting laser 10-15, it is possible to provide a surface emitting laser array capable of controlling polarization directions of a plurality of light emitting sections arranged in a circling manner to one polarization direction different from each other.

In the surface emitting laser 10-15, the multilayer film reflecting mirror 109 or the reflective film 110 may be provided on at least one reflection surface.

### 16. Surface Emitting Laser According to Example 16 of One Embodiment of Present Technology

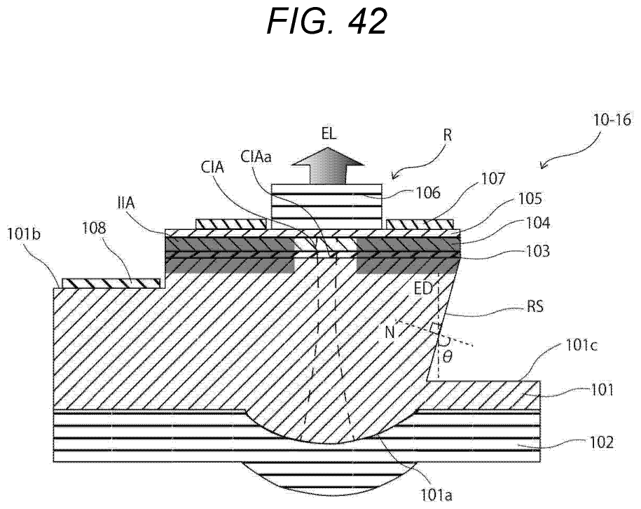

Hereinafter, a surface emitting laser according to Example 16 of one embodiment of the present technology will be described with reference to the drawings. FIG. 42 is a cross-sectional view of a surface emitting laser 10-16 according to Example 16 of one embodiment of the present technology.

As illustrated in FIG. 42, the surface emitting laser 10-16 has a configuration substantially similar to the surface emitting laser 10-1 according to Example 1 except that an angle O which is smaller one of angles formed by the normal line N of the reflection surface RS and the emission direction ED is an acute angle.

In the surface emitting laser 10-16, the reflection surface RS is a side surface (inclined surface) of the notch 101c provided in the substrate 101, and is inclined so as to approach the current injection region CIA as approaching the back surface (lower surface) of the substrate 101 in plan view. The notch 101c can be formed by, for example, oblique etching.

In the surface emitting laser 10-16, since the reflection surface RS is inclined with respect to the emission direction, optical confinement in the longitudinal direction and the lateral direction by the reflection surface RS occurs, and light can be propagated in an oblique direction. As a result, the light propagating in the longitudinal direction and the light propagating in the oblique direction are coupled in the resonator R, and the polarization direction of the emitted light can be controlled to one polarization direction.

In the surface emitting laser 10-16, the multilayer film reflecting mirror 109 or the reflective film 110 may be provided on the reflection surface RS.

### 17. Surface Emitting Laser According to Example 17 of One Embodiment of Present Technology

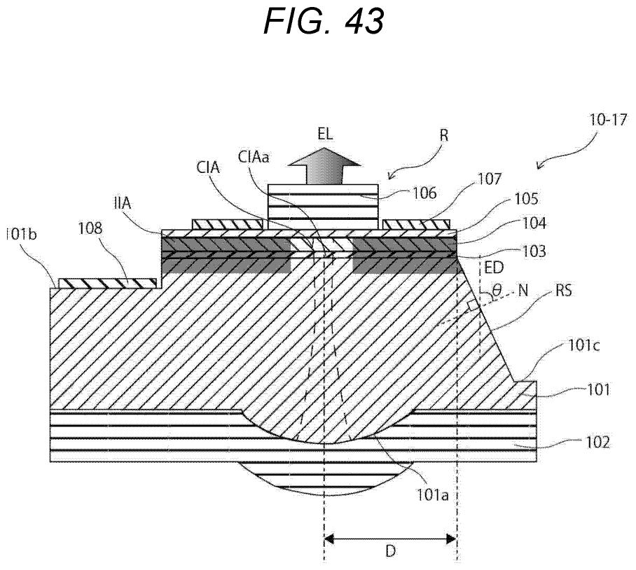

Hereinafter, a surface emitting laser according to Example 17 of one embodiment of the present technology will be described with reference to the drawings. FIG. 43 is a cross-sectional view of a surface emitting laser 10-17 according to Example 17 of one embodiment of the present technology.

As illustrated in FIG. 43, the surface emitting laser 10-17 has a configuration substantially similar to the surface emitting laser 10-1 according to Example 1 except that an angle θ which is smaller one of angles formed by the normal line N of the reflection surface RS and the emission direction ED is an acute angle.

In the surface emitting laser 10-17, the reflection surface RS is a side surface (inclined surface) of the notch 101c provided in the substrate 101, and is inclined so as to be away from the current injection region CIA as approaching the back surface (lower surface) of the substrate 101 in plan view. The notch 101c can be formed by, for example, oblique etching.

In the surface emitting laser 10-17, since the reflection surface RS is inclined with respect to the emission direction, optical confinement in the longitudinal direction and the lateral direction by the reflection surface RS occurs, and light can be propagated in an oblique direction. As a result, the light propagating in the longitudinal direction and the light propagating in the oblique direction are coupled in the resonator R, and the polarization direction of the emitted light can be controlled to one polarization direction.

In the surface emitting laser 10-17, the multilayer film reflecting mirror 109 or the reflective film 110 may be provided on the reflection surface RS.

### 18. Surface Emitting Laser According to Example 18 of One Embodiment of Present Technology

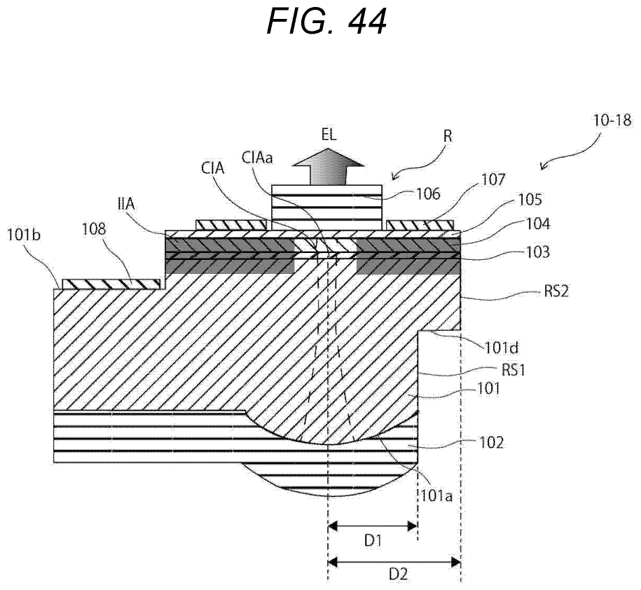

Hereinafter, a surface emitting laser according to Example 18 of one embodiment of the present technology will be described with reference to the drawings. FIG. 44 is a cross-sectional view of a surface emitting laser 10-18 according to Example 18 of one embodiment of the present technology.

As illustrated in FIG. 44, the surface emitting laser 10-18 has a stepped portion 101d on one side surface (a side surface on the right side with respect to the paper surface of FIG. 44) of the resonator R, a left step (a surface on the left side with respect to the paper surface of FIG. 44) of the stepped portion 101d on the one side surface is the first reflection surface RS1, and a right step (a surface on the right side with respect to the paper surface of FIG. 44) of the stepped portion 101d on the one side surface is the second reflection surface RS2. Here, the first and second reflection surfaces RS1 and RS2 are parallel to each other, and the first reflection surface RS1 is located closer to the current injection region CIA than the second reflection surface RS2 in plan view. That is, D2>D1 holds for the distance D1 in the in-plane direction between the first reflection surface RS1 and the center CIAa of the current injection region CIA and the distance D2 in the in-plane direction between the second reflection surface RS2 and the center CIAa of the current injection region CIA.

In the surface emitting laser 10-18, since the distances between the first and second reflection surfaces RS1 and RS2 and the center CIAa of the current injection region CIA are different from each other in plan view, the magnitude of optical confinement in the lateral direction can be made different depending on the position of one side surface of the resonator R in the longitudinal direction. specifically, the lateral optical confinement by the first reflection surface RS1 can be made larger than the lateral optical confinement by the second reflection surface RS2.

Note that the stepped portion 101d may be formed such that D1>D2. One of the first and second reflection surfaces RS1 and RS2 may not be a substantially reflection surface (may be a normal end face having a reflectance of less than 10%). In the surface emitting laser 10-18, the multilayer film reflecting mirror 109 or the reflective film 110 may be provided on at least one of the first or second reflection surfaces RS1 or RS2.

### 19. Surface Emitting Laser According to Example 19 of One Embodiment of Present Technology

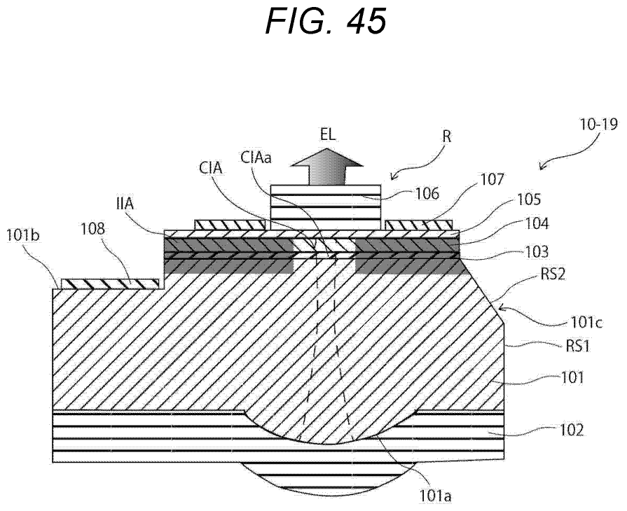

Hereinafter, a surface emitting laser according to Example 19 of one embodiment of the present technology will be described with reference to the drawings. FIG. 45 is a cross-sectional view of a surface emitting laser 10-19 according to Example 19 of one embodiment of the present technology.

As illustrated in FIG. 45, the surface emitting laser 10-19 has a notch 101c at a corner portion of the substrate 101 (an upper right corner portion with respect to the paper surface of FIG. 45). The notch 101c can be formed by, for example, oblique etching.

In the surface emitting laser 10-19, one end face of the substrate 101 has a first reflection surface RS1 whose normal line is perpendicular to the emission direction, and a second reflection surface RS2 extending obliquely upward from the upper end of the first reflection surface RS1 and constituting a side surface (inclined surface) of the notch 101c.

In the surface emitting laser 10-19, optical confinement in the lateral direction by the first reflection surface RS and optical confinement in the longitudinal direction and the lateral direction by the second reflection surface RS occur, and light can be propagated in the lateral direction and the oblique direction in the slab waveguide. As a result, the light propagating in the longitudinal direction and the light propagating in the lateral direction and the oblique direction are coupled in the resonator R, and the polarization direction of the emitted light can be controlled to one polarization direction.

Note that one of the first and second reflection surfaces RS1 and RS2 may not be substantially a reflection surface (may be a normal end face having a reflectance of less than 10%). In the surface emitting laser 10-19, the multilayer film reflecting mirror 109 or the reflective film 110 may be provided on at least one of the first or second reflection surfaces RS1 or RS2.

### 20. Surface Emitting Laser According to Example 20 of One Embodiment of Present Technology

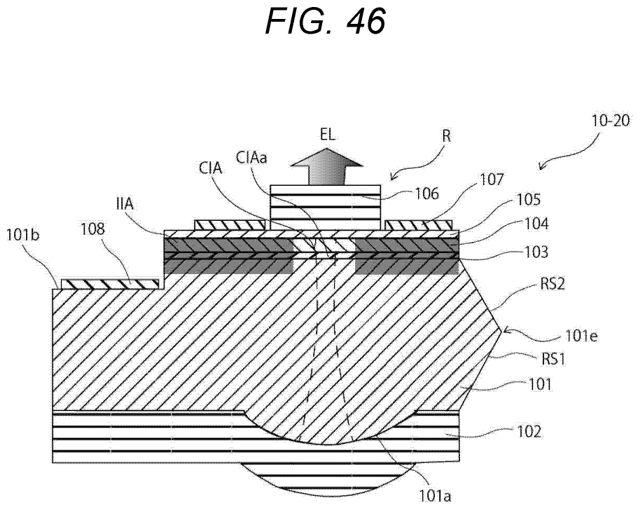

Hereinafter, a surface emitting laser according to Example 20 of one embodiment of the present technology will be described with reference to the drawings. FIG. 46 is a cross-sectional view of a surface emitting laser 10-20 according to Example 20 of one embodiment of the present technology.

In the surface emitting laser 10-20, as illustrated in FIG. 46, a ridge 101e that is convex in a direction away from the current injection region CIA in the plane and extends in the horizontal direction orthogonal to the convex direction is provided on one end face of the substrate 101. The ridge 101e can be formed by, for example, oblique etching.

Here, the substrate 101 has a first reflection surface RS1 constituting a lower inclined surface of the ridge 101e and a second reflection surface RS2 constituting an upper inclined surface.

In the surface emitting laser 10-20, optical confinement in the longitudinal direction and the lateral direction by the first reflection surface RS and optical confinement in the longitudinal direction and the lateral direction by the second reflection surface RS occur, and light can be propagated in oblique directions intersecting each other in the slab waveguide. As a result, the light propagating in the longitudinal direction and the light propagating in the oblique direction intersecting each other are coupled in the resonator R, and the polarization direction of the emitted light can be controlled to one polarization direction.

Note that one of the first and second reflection surfaces RS1 and RS2 may not be substantially a reflection surface (may be a normal end face having a reflectance of less than 10%). In the surface emitting laser 10-20, the multilayer film reflecting mirror 109 or the reflective film 110 may be provided on at least one of the first or second reflection surfaces RS1 or RS2.

### 21. Surface Emitting Laser According to Example 21 of One Embodiment of Present Technology

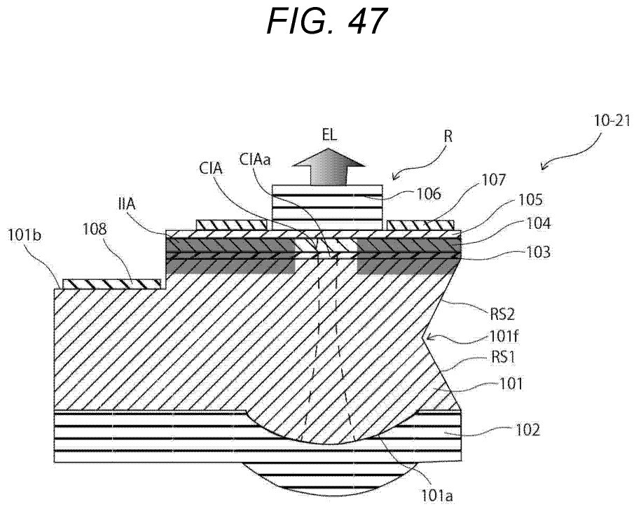

Hereinafter, a surface emitting laser according to Example 21 of one embodiment of the present technology will be described with reference to the drawings. FIG. 47 is a cross-sectional view of a surface emitting laser 10-21 according to Example 21 of one embodiment of the present technology.

In the surface emitting laser 10-21, as illustrated in FIG. 47, a recessed ridge 101f that is recessed in a direction approaching the current injection region CIA in a plane and extends in a horizontal direction orthogonal to the recessed direction is provided on one end face of the substrate 101. The recessed ridge 101f can be formed by, for example, oblique etching.

Here, the substrate 101 has a first reflection surface RS1 constituting a lower inclined surface of the recessed ridge 101f and a second reflection surface RS2 constituting an upper inclined surface.

In the surface emitting laser 10-21, optical confinement in the longitudinal direction and the lateral direction by the first reflection surface RS and optical confinement in the longitudinal direction and the lateral direction by the second reflection surface RS occur, and light can be propagated in oblique directions intersecting each other in the slab waveguide. As a result, the light propagating in the longitudinal direction and the light propagating in the oblique direction intersecting each other are coupled in the resonator R, and the polarization direction of the emitted light can be controlled to one polarization direction.

Note that one of the first and second reflection surfaces RS1 and RS2 may not be substantially a reflection surface (may be a normal end face having a reflectance of less than 10%). In the surface emitting laser 10-21, the multilayer film reflecting mirror 109 or the reflective film 110 may be provided on at least one of the first or second reflection surfaces RS1 or RS2.

### 22. Surface Emitting Laser According to Example 22 of One Embodiment of Present Technology

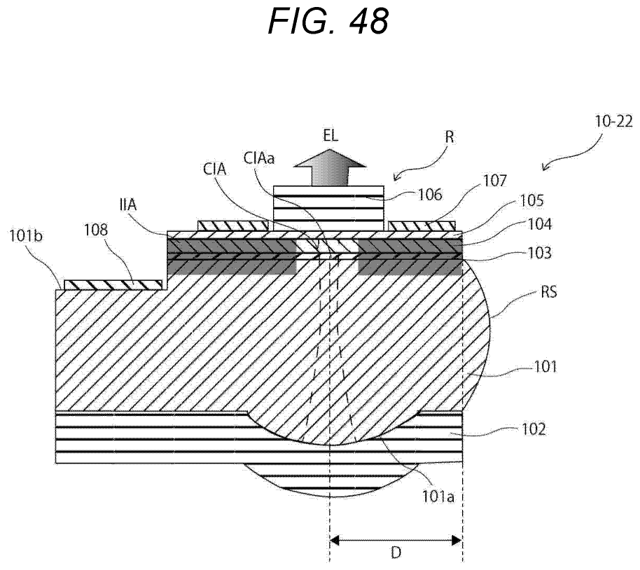

Hereinafter, a surface emitting laser according to Example 22 of one embodiment of the present technology will be described with reference to the drawings. FIG. 48 is a cross-sectional view of a surface emitting laser 10-22 according to Example 22 of one embodiment of the present technology.

In the surface emitting laser 10-22, as illustrated in FIG. 48, the reflection surface RS, which is one end face of the substrate 101, is curved so as to be convex in a direction away from the current injection region CIA in the plane, and is a curved surface extending in the horizontal direction orthogonal to the convex direction. The curved surface as the reflection surface RS functions as a concave mirror. The curved surface can be formed by a method similar to the method of forming the lens-shaped portion 101a.

In the surface emitting laser 10-22, light can be propagated in the substantially lateral direction while reducing diffraction loss in the slab waveguide by optical confinement in the longitudinal direction and the lateral direction by the concave mirror as the reflection surface RS. As a result, in the resonator R, the coupling efficiency between the light propagating in the longitudinal direction and the light propagating in the substantially lateral direction can be improved, and the polarization direction of the emitted light can be more stably controlled in one polarization direction.

In the surface emitting laser 10-22, the multilayer film reflecting mirror 109 or the reflective film 110 may be provided on the reflection surface RS.

### 23. Surface Emitting Laser According to Example 23 of One Embodiment of Present Technology

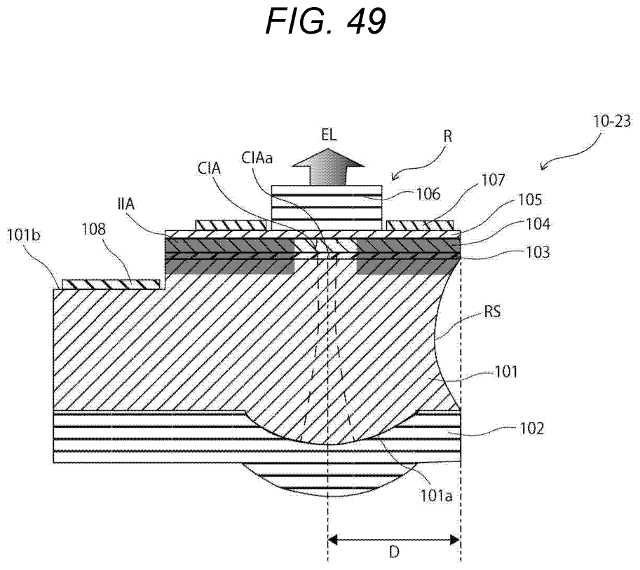

Hereinafter, a surface emitting laser according to Example 23 of one embodiment of the present technology will be described with reference to the drawings. FIG. 49 is a cross-sectional view of a surface emitting laser 10-23 according to Example 23 of one embodiment of the present technology.

In the surface emitting laser 10-23, as illustrated in FIG. 49, the reflection surface RS, which is one end face of the substrate 101, is curved so as to be recessed in a direction approaching the current injection region CIA in the plane, and is a curved surface extending in the horizontal direction orthogonal to the recessed direction. The curved surface as the reflection surface RS functions as a convex mirror. The curved surface can be formed by a method according to the method for forming the lens-shaped portion 101a.

In the surface emitting laser 10-23, light can be propagated in the substantially lateral direction in the slab waveguide by optical confinement in the substantially lateral direction by the reflection surface RS. As a result, the light propagating in the longitudinal direction and the light propagating in the substantially lateral direction are coupled in the resonator R, and the polarization direction of the emitted light can be controlled to one polarization direction.

In the surface emitting laser 10-23, the multilayer film reflecting mirror 109 or the reflective film 110 may be provided on the reflection surface RS.

### 24. Surface Emitting Laser According to Example 24 of One Embodiment of Present Technology

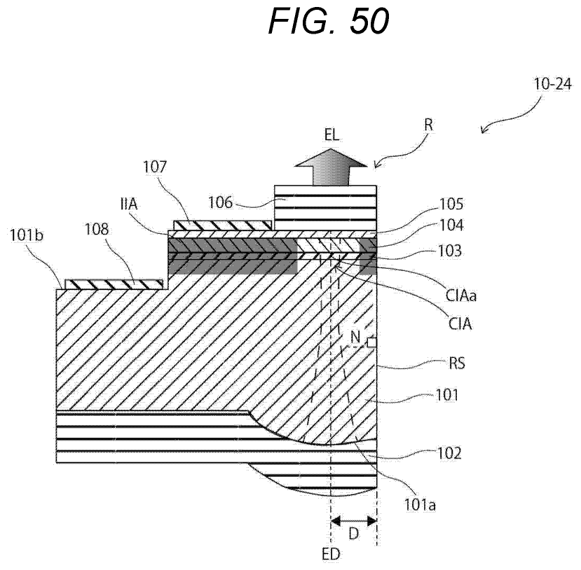

Hereinafter, a surface emitting laser according to Example 24 of one embodiment of the present technology will be described with reference to the drawings. FIG. 50 is a cross-sectional view of a surface emitting laser 10-24 according to Example 24 of one embodiment of the present technology.

As illustrated in FIG. 50, the surface emitting laser 10-24 has a configuration substantially similar to the surface emitting laser 10-1 according to Example 1 except that the entire side surface of the resonator R is a reflection surface RS.

Here, the normal line N of the reflection surface RS is perpendicular to the emission direction ED, but may be inclined with respect to the emission direction ED. The reflection surface RS is, for example, a cleaved surface.

In the surface emitting laser 10-24, since the reflection surface RS is the entire side surface of the resonator R, it is possible to couple light propagating in the longitudinal direction and light propagating in the oblique direction in the resonator R over the entire region in the thickness direction of the resonator R, and it is possible to more stably control the polarization direction in one direction.

In the surface emitting laser 10-24, the multilayer film reflecting mirror 109 or the reflective film 110 may be provided on the reflection surface RS.

### 25. Surface Emitting Laser According to Example 25 of One Embodiment of Present Technology

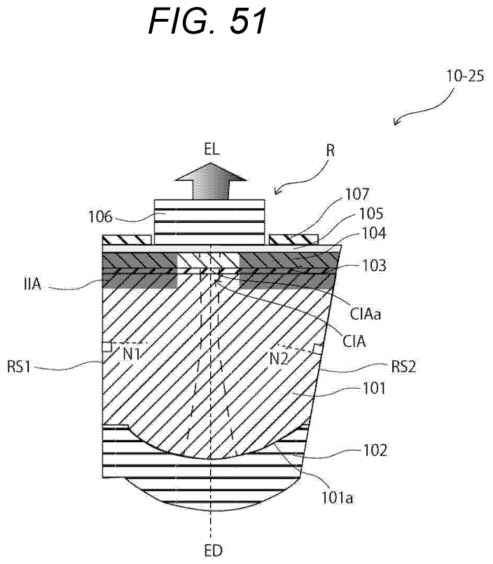

Hereinafter, a surface emitting laser according to Example 25 of one embodiment of the present technology will be described with reference to the drawings. FIG. 51 is a cross-sectional view of a surface emitting laser 10-25 according to Example 25 of one embodiment of the present technology.

As illustrated in FIG. 51, the surface emitting laser 10-25 has a configuration similar to the surface emitting laser 10-3 according to Example 3 except that the first and second reflection surfaces RS1 and RS2 are not parallel to each other.

Here, the normal line N1 of the first reflection surface RS1 is perpendicular to the emission direction ED, and the smaller of the angles formed by the normal line N2 of the second reflection surface RS2 and the emission direction ED is the acute angle.

In the surface emitting laser 10-25, light can be propagated in the lateral direction and the oblique direction in the slab waveguide by optical confinement in the lateral direction by the first reflection surface RS1 and optical confinement in the longitudinal direction and the lateral direction by the second reflection surface RS2. As a result, the light propagating in the longitudinal direction and the light propagating in the lateral direction and the oblique direction are coupled in the resonator R, and the polarization direction of the emitted light can be controlled to one polarization direction.

In the surface emitting laser 10-25, the multilayer film reflecting mirror 109 or the reflective film 110 may be provided on at least one of the first or second reflection surfaces RS1 or RS2.

### 26. Surface Emitting Laser According to Example 26 of One Embodiment of Present Technology

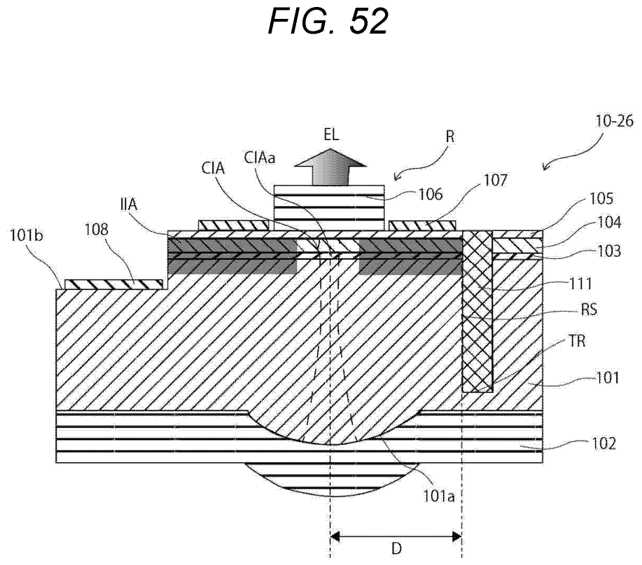

Hereinafter, a surface emitting laser according to Example 26 of one embodiment of the present technology will be described with reference to the drawings. FIG. 52 is a cross-sectional view of a surface emitting laser 10-26 according to Example 26 of one embodiment of the present technology.

As illustrated in FIG. 52, the surface emitting laser 10-26 has a configuration similar to the surface emitting laser 10-8 according to Example 8 except that the reflection portion includes a low refractive index film 111 provided in the trench TR in addition to the reflection surface RS.

The low refractive index film 111 is constituted by a material having a refractive index lower than that of the substrate 101. Examples of the material of the low refractive index film 111 include dielectrics such as SiO₂, SiN, and SiON.

In the surface emitting laser 10-26, the interface between the side surface of the trench TR closer to the current injection region CIA and the side surface of the low refractive index film 111 closer to the current injection region CIA is the reflection surface RS. That is, the reflection surface RS includes an interface between the semiconductor and the dielectric.

According to the surface emitting laser 10-26, the reflectance of the entire reflection portion can be adjusted by the refractive index difference between the substrate 101 and the low refractive index film 111.

### 27. Modifications of Present Technology

The present technology is not limited to the above examples, and various modifications can be made.

For example, it is sufficient that the reflection surface of the reflection portion includes at least a part of an end face of any one of the first reflecting mirror 102, the substrate 101, the active layer 103, the cladding layer 104, and the transparent conductive film 105 or at least a part of a side surface of a groove provided in the resonator R.

The surface emitting laser according to the present technology is preferably constituted by a group III-V compound semiconductor. Specifically, the present technology can also be applied to an InP-based surface emitting laser, a GaAs surface emitting laser, and the like instead of the GaN-based surface emitting laser described above.

At least one of the first or second reflecting mirrors 102 or 106 may be, for example, a semiconductor multilayer film reflecting mirror, a hybrid mirror including a semiconductor multilayer film reflecting mirror and a metal reflecting mirror, a hybrid mirror including a semiconductor multilayer film reflecting mirror and a dielectric multilayer film reflecting mirror, a hybrid mirror including a dielectric multilayer film reflecting mirror and a metal reflecting mirror, or the like.

The conductivity types (p-type and n-type) of the constituent layers of the surface emitting laser according to each of the above examples may be interchanged.

A part of the configurations of the surface emitting lasers according to the above examples may be combined within a range not contradictory to each other.

In each of the above examples, the material, thickness, width, length, shape, size, arrangement, and the like of each component constituting the surface emitting laser can be appropriately changed within a range functioning as the surface emitting laser.

### 28. Application Example to Electronic Equipment

The technology (present technology) according to the present disclosure can be applied to various products (electronic equipment). For example, the technology according to the present disclosure may be realized as an apparatus (for example, a ranging apparatus, a shape recognition apparatus, or the like) or a low power consumption device (smartphone, smart watch, tablet, mouse, or the like) mounted on any type of mobile body such as an automobile, an electric vehicle, a hybrid electric vehicle, a motorcycle, a bicycle, a personal mobility, an airplane, a drone, a ship, or a robot.

The surface emitting laser according to the present technology can also be applied as, for example, a light source or a display itself of equipment (for example, a laser printer, a laser copier, a projector, a head-mounted display, a head-up display, or the like) that forms or displays an image by laser light.

### 29. Example in Which Surface Emitting Laser Is Applied to Distance Measurement Apparatus

Hereinafter, application examples of the surface emitting laser according to each of the above-described embodiments and modifications will be described.

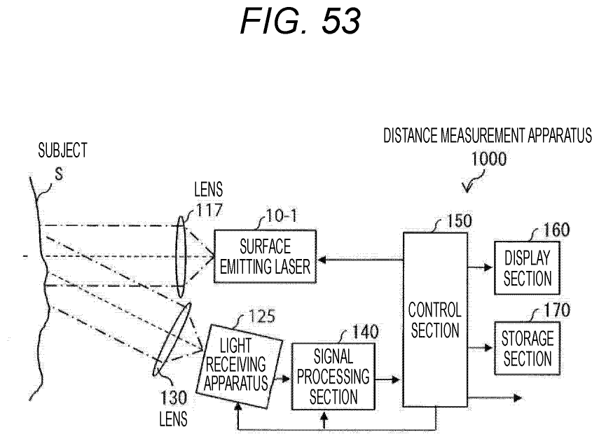

FIG. 53 illustrates an example of a schematic configuration of a distance measurement apparatus 1000 (ranging apparatus) including a surface emitting laser 10-1 as an example of electronic equipment according to the present technology. The distance measurement apparatus 1000 measures the distance to the subject S by a time of flight (TOF) method. The distance measurement apparatus 1000 includes the surface emitting laser 10-1 as a light source. The distance measurement apparatus 1000 includes, for example, the surface emitting laser 10-1, a light receiving apparatus 125, lenses 117 and 130, a signal processing section 140, a control section 150, a display section 160, and a storage section 170.

The surface emitting laser 10-1 is driven by a laser driver (driver). The laser driver has an anode terminal and a cathode terminal connected to an anode electrode and a cathode electrode of the surface emitting laser 10-1 via wiring or a conductive bump, respectively. The laser driver includes, for example, a circuit element such as a capacitor or a transistor.

The light receiving apparatus 125 detects light reflected by the subject S. The lens 117 is a lens for collimating the light emitted from the surface emitting laser 10-1, and is a collimating lens. The lens 130 is a condenser lens that collects the light reflected by the subject S and guides the light to the light receiving apparatus 125.

The signal processing section 140 is a circuit for generating a signal corresponding to a difference between the signal input from the light receiving apparatus 125 and the reference signal input from the control section 150. The control section 150 includes, for example, a time to digital converter (TDC). The reference signal may be a signal input from the control section 150, or may be an output signal of a detection section that directly detects the output of the surface emitting laser 10-1. The control section 150 is, for example, a processor that controls the surface emitting laser 10-1, the light receiving apparatus 125, the signal processing section 140, the display section 160, and the storage section 170. The control section 150 is a circuit that measures the distance to the subject S on the basis of the signal generated by the signal processing section 140. The control section 150 generates a video signal for displaying information on the distance to the subject S, and outputs the video signal to the display section 160. The display section 160 displays information on the distance to the subject S on the basis of the video signal input from the control section 150. The control section 150 stores information on the distance to the subject S in the storage section 170.

In the present application example, instead of the surface emitting laser 10-1, any one of the surface emitting lasers 10-2 to 10-26 according to Example 2 to 26 described above can be applied to the distance measurement apparatus 1000. Note that, in a case where a surface emitting laser (surface emitting laser array) having a plurality of light emitting sections is applied to the distance measurement apparatus 1000, a laser driver that individually drives the plurality of light emitting sections can also be used.

### 30. Example in Which Distance Measurement Apparatus Is Mounted on Mobile Body

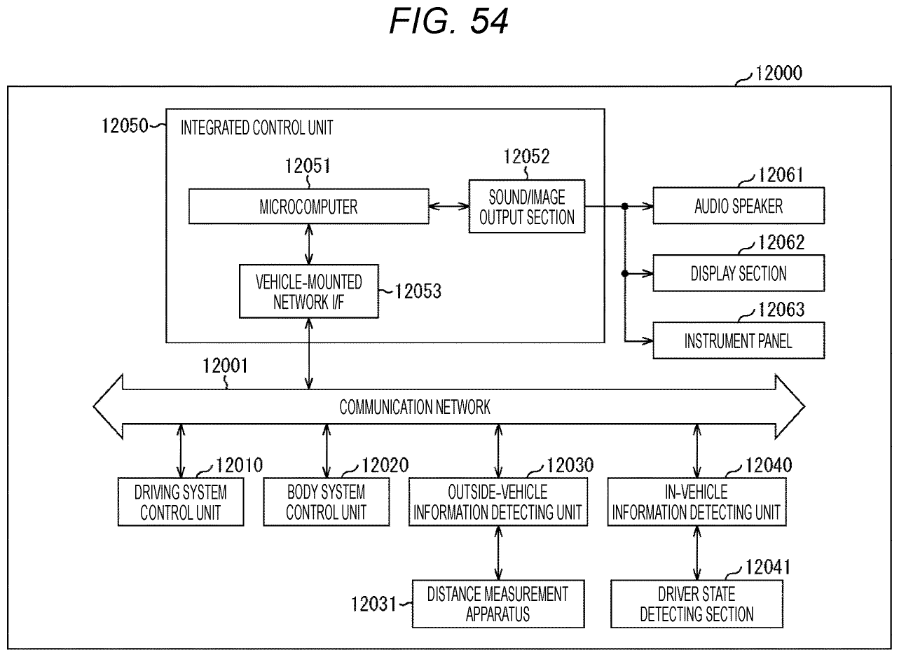

FIG. 54 is a block diagram depicting an example of schematic configuration of a vehicle control system as an example of a mobile body control system to which the technology according to an embodiment of the present disclosure can be applied.

The vehicle control system 12000 includes a plurality of electronic control units connected via a communication network 12001. In the example illustrated in FIG. 54, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of apparatuses related to the drive system of the vehicle according to various programs. For example, the driving system control unit 12010 functions as a control apparatus of a driving force generating apparatus for generating a driving force of the vehicle such as an internal combustion engine or a driving motor, a driving force transmitting mechanism for transmitting the driving force to wheels, a steering mechanism for adjusting a steering angle of the vehicle, a braking apparatus for generating a braking force of the vehicle, and the like.

The body system control unit 12020 controls operations of various apparatuses mounted on the vehicle body according to various programs. For example, the body system control unit 12020 functions as a control apparatus of a keyless entry system, a smart key system, a power window apparatus, or various lamps such as a headlamp, a backup lamp, a brake lamp, a turn signal, or a fog lamp. In this case, radio waves transmitted from a portable device that substitutes for a key or signals of various switches can be input to the body system control unit 12020. The body system control unit 12020 receives input of these radio waves or signals, and controls a door lock apparatus, a power window apparatus, a lamp, and the like of the vehicle.

The outside-vehicle information detecting unit 12030 detects information outside the vehicle on which the vehicle control system 12000 is mounted. For example, a distance measurement apparatus 12031 is connected to the outside-vehicle information detecting unit 12030. The distance measurement apparatus 12031 includes the above-described distance measurement apparatus 1000. The outside-vehicle information detecting unit 12030 causes the distance measurement apparatus 12031 to measure a distance to an object outside the vehicle (subject S), and acquires distance data obtained by the measurement. The outside-vehicle information detecting unit 12030 may perform object detection processing of a person, a vehicle, an obstacle, a sign, or the like on the basis of the acquired distance data.

The in-vehicle information detecting unit 12040 detects information inside the vehicle. For example, a driver state detecting section 12041 that detects a state of a driver is connected to the in-vehicle information detecting unit 12040. The driver state detecting section 12041 includes, for example, a camera that images the driver, and the in-vehicle information detecting unit 12040 may calculate the degree of fatigue or the degree of concentration of the driver or may determine whether or not the driver is dozing off on the basis of the detection information input from the driver state detecting section 12041.

The microcomputer 12051 can calculate a control target value of the driving force generating apparatus, the steering mechanism, or the braking apparatus on the basis of the information inside and outside the vehicle acquired by the outside-vehicle information detecting unit 12030 or the in-vehicle information detecting unit 12040, and output a control command to the driving system control unit 12010. For example, the microcomputer 12051 can perform cooperative control for the purpose of implementing functions of an advanced driver assistance system (ADAS) including collision avoidance or shock mitigation of the vehicle, follow-up traveling based on an inter-vehicle distance, vehicle speed maintaining traveling, vehicle collision warning, vehicle lane departure warning, or the like.

Furthermore, the microcomputer 12051 controls the driving force generating apparatus, the steering mechanism, the braking apparatus, or the like on the basis of the information around the vehicle acquired by the outside-vehicle information detecting unit 12030 or the in-vehicle information detecting unit 12040, thereby performing cooperative control for the purpose of automated driving or the like in which the vehicle autonomously travels without depending on the operation of the driver.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control for the purpose of preventing glare, such as switching from a high beam to a low beam, by controlling the headlamp according to the position of a preceding vehicle or an oncoming vehicle detected by the outside-vehicle information detecting unit 12030.

The sound/image output section 12052 transmits an output signal of at least one of a sound or an image to an output apparatus capable of visually or auditorily notifying a passenger of the vehicle or the outside of the vehicle of information. In the example of FIG. 54, an audio speaker 12061, a display section 12062, and an instrument panel 12063 are illustrated as the output device. The display section 12062 may include, for example, at least one of an on-board display or a head-up display.

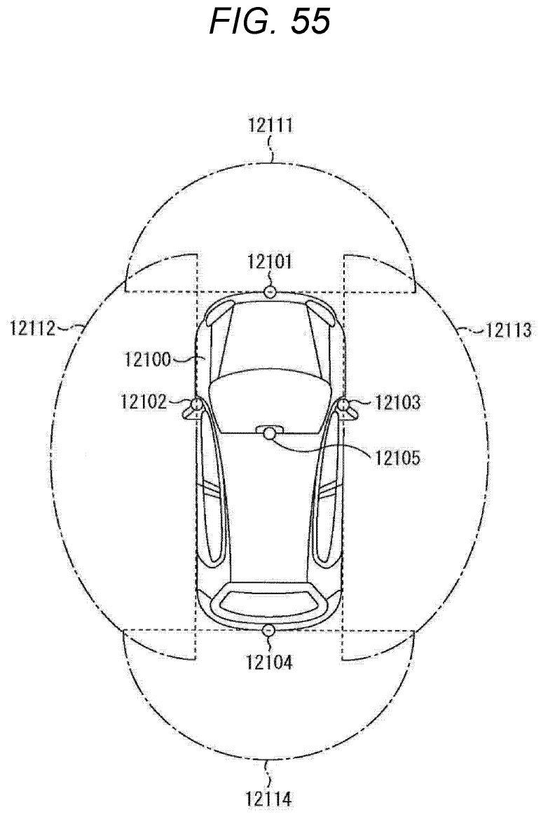

FIG. 55 is a diagram illustrating an example of an installation position of the distance measurement apparatus 12031.

In FIG. 55, a vehicle 12100 includes distance measurement apparatuses 12101, 12102, 12103, 12104, and 12105 as distance measurement apparatus 12031.

The distance measurement apparatuses 12101, 12102, 12103, 12104, and 12105 are provided, for example, at positions such as a front nose, a sideview mirror, a rear bumper, a back door, and an upper portion of a windshield in a vehicle interior of the vehicle 12100. The distance measurement apparatus 12101 provided at the front nose and the distance measurement apparatus 12105 provided at the upper portion of the windshield in the vehicle interior mainly acquire data in front of the vehicle 12100. The distance measurement apparatuses 12102 and 12103 provided at the sideview mirrors mainly acquire data on the sides of the vehicle 12100. The distance measurement apparatus 12104 provided on the rear bumper or the back door mainly acquires data on the rear side of the vehicle 12100. The forward data acquired by the distance measurement apparatuses 12101 and 12105 is mainly used for detecting a preceding vehicle, a pedestrian, an obstacle, a traffic signal, a traffic sign, or the like.

Note that FIG. 55 illustrates an example of detection ranges of the distance measurement apparatuses 12101 to 12104. A detection range 12111 indicates a detection range of the distance measurement apparatus 12101 provided on the front nose, detection ranges 12112 and 12113 indicate detection ranges of the distance measurement apparatuses 12102 and 12103 provided on the sideview mirrors, respectively, and a detection range 12114 indicates a detection range of the distance measurement apparatus 12104 provided on the rear bumper or the back door.

For example, the microcomputer 12051 obtains a distance to each three-dimensional object in the detection ranges 12111 to 12114 and a temporal change of the distance (relative speed with respect to the vehicle 12100) on the basis of the distance data obtained from the distance measurement apparatuses 12101 to 12104, thereby extracting, as a preceding vehicle, a three-dimensional object traveling at a predetermined speed (for example, 0 km/h or more) in substantially the same direction as the vehicle 12100, in particular, the closest three-dimensional object on a traveling path of the vehicle 12100. Furthermore, the microcomputer 12051 can set an inter-vehicle distance to be secured in advance in front of the preceding vehicle, and can perform automatic brake control (including follow-up stop control), automatic acceleration control (including follow-up start control), and the like. As described above, it is possible to perform cooperative control for the purpose of automated driving or the like in which the vehicle autonomously travels without depending on the operation of the driver.

For example, on the basis of the distance data obtained from the distance measurement apparatuses 12101 to 12104, the microcomputer 12051 can classify three-dimensional object data regarding three-dimensional objects into two-wheeled vehicles, standard-sized vehicles, large-sized vehicles, pedestrians, and other three-dimensional objects such as utility poles, extract the three-dimensional object data, and use the three-dimensional object data for automatic avoidance of obstacles. For example, the microcomputer 12051 identifies obstacles around the vehicle 12100 as obstacles that can be visually recognized by the driver of the vehicle 12100 and obstacles that are difficult to visually recognize. Then, the microcomputer 12051 determines a collision risk indicating a risk of collision with each obstacle, and when the collision risk is a set value or more and there is a possibility of collision, the microcomputer can perform driving assistance for collision avoidance by outputting an alarm to the driver via the audio speaker 12061 or the display section 12062 or performing forced deceleration or avoidance steering via the driving system control unit 12010.

An example of the mobile body control system to which the technology according to the present disclosure can be applied has been described above. The technology according to the present disclosure can be applied to the distance measurement apparatus 12031 among the configurations described above.

Furthermore, the present technology can also have the following configurations.
(1) A surface emitting laser including a resonator including:
first and second reflecting mirrors laminated on each other; and
an active layer disposed between the first and second reflecting mirrors,
the resonator further including a reflection portion having a reflection surface, in which
the reflection portion is located outside a current injection region of the active layer in plan view, and
a normal line of the reflection surface is not parallel to an emission direction.
(2) The surface emitting laser according to (1), in which the resonator has a current confinement region that sets the current injection region.
(3) The surface emitting laser according to (1) or
(2), in which a smaller one of angles formed by the normal line and the emission direction is 30° or more and 90° or less.
(4) The surface emitting laser according to any one of (1) to (3), in which the reflection surface is at least a part of a side surface of the resonator or at least a part of a side surface of a groove provided in the resonator.
(5) The surface emitting laser according to any one of (1) to (4), in which the reflection surface is an entire side surface of the resonator or an entire side surface of a groove provided in the resonator.
(6) The surface emitting laser according to any one of (1) to (5), in which the reflection surface is constituted by a cleaved surface.
(7) The surface emitting laser according to any one of (1) to (6), in which the resonator includes a slab waveguide that propagates light in a direction non-Parallel to the emission direction.
(8) The surface emitting laser according to any one of (1) to (7), in which the resonator has a refractive index distribution in a lateral direction of 5% or less.
(9) The surface emitting laser according to any one of (1) to (8), in which a length of the reflection surface in the emission direction occupies 25% or more of a thickness of the resonator.
(10) The surface emitting laser according to any one of (1) to (9), in which the resonator includes a substrate disposed between the first reflecting mirror and the active layer, and the substrate has at least a part of the reflection surface.
(11) The surface emitting laser according to any one of (1) to (10), including a plurality of the reflection portions.
(12) The surface emitting laser according to (11), in which each of the reflection surfaces of at least two of the plurality of the reflection portions is non-parallel to each other.
(13) The surface emitting laser according to (11) or (12), in which each of the reflection surfaces of at least two of the plurality of the reflection portions is parallel to each other.
(14) The surface emitting laser according to any one of (11) to (13), in which the active layer has a plurality of the current injection regions, and the plurality of the reflection portions is provided individually corresponding to the plurality of the current injection regions.
(15) The surface emitting laser according to any one of (11) to (13), in which the active layer has a plurality of the current injection regions, and the plurality of the reflection portions is provided in common in the plurality of the current injection regions.
(16) The surface emitting laser according to any one of (11) to (13), in which the active layer has a plurality of the current injection regions, and some of the plurality of the reflection portions are provided in common in some of the plurality of the current injection regions, and the others of the plurality of the reflection portions are provided in common in the others of the plurality of the current injection regions.
(17) The surface emitting laser according to any one of (1) to (10), in which the active layer has a plurality of the current injection regions, and the reflection portion is provided in common in the plurality of the current injection regions.
(18) The surface emitting laser according to any one of (1) to (17), in which the reflection portion has a reflecting structure provided on the reflection surface.
(19) The surface emitting laser according to any one of (1) to (18), in which a shortest distance in an in-plane direction between an outer edge of the first reflecting mirror and the reflection surface is 1000 μm or less.
(20) The surface emitting laser according to any one of (1) to (19), in which a distance in an in-plane direction between a center of the current injection region and the reflection surface is 1000 μm or less.
(21) The surface emitting laser according to (18), in which the reflecting structure is a multilayer film reflecting mirror, a metal film, or a dielectric film.
(22) The surface emitting laser according to any one of (1) to (21), in which a resonator length of the resonator is 10 μm or more.
(23) The surface emitting laser according to any one of (1) to (22), in which the first reflecting mirror is a concave mirror.
(24) The surface emitting laser according to any one of (1) to (23), in which the reflection surface includes at least one of an interface between a semiconductor and air, an interface between a semiconductor and a dielectric, an interface between a dielectric and a semiconductor having a laminated structure, an interface between a semiconductor and a metal, an interface between a dielectric and air, or an interface between a semiconductor and a semiconductor having a laminated structure.
(25) Electronic equipment including the surface emitting laser according to any one of (1) to (24).
(26) A manufacturing method of a surface emitting laser, the manufacturing method including:
a step of forming an active layer and first and second reflecting mirrors sandwiching the active layer on a substrate to generate a resonator; and
a step of cleaving the resonator at a position outside a current injection region of the active layer in plan view to form a reflection surface whose normal line is not parallel to an emission direction.
(27) A manufacturing method of a surface emitting laser, the manufacturing method including a step of forming an active layer and first and second reflecting mirrors sandwiching the active layer on a substrate to generate a resonator, in which
the step includes a sub-step of etching at least the substrate among the substrate, the active layer, and the first and second reflecting mirrors to form a reflection surface whose normal line is not parallel to an emission direction.

### REFERENCE SIGNS LIST

10-1 to 10-26 Surface emitting laser
101 Substrate
102 First reflecting mirror
103 Active layer
106 Second reflecting mirror
107 Substrate
109 Multilayer film reflecting mirror (reflecting structure)
110 Reflective film (reflecting structure)
R Resonator
RS, RS1, RS2, RS3, RS4, RS5, RS6 Reflection surface
CIA Current injection region
CIAa Center of current injection region
N Normal line
ED Emission direction
IIA Ion implantation region (current confinement region)
θ Smaller one of angles formed by normal line and emission direction
D Distance in in-plane direction between center of current injection region and reflection surface
SD Shortest distance in in-plane direction between first reflecting mirror and reflection surface

1. A surface emitting laser comprising a resonator including:
first and second reflecting mirrors laminated on each other; and
an active layer disposed between the first and second reflecting mirrors,
the resonator further including a reflection portion having a reflection surface, wherein
the reflection portion is located outside a current injection region of the active layer in plan view, and
a normal line of the reflection surface is not parallel to an emission direction.

2. The surface emitting laser according to claim 1, wherein the resonator has a current confinement region that sets the current injection regions.

3. The surface emitting laser according to claim 1, wherein a smaller one of angles formed by the normal line and the emission direction is 30° or more and 90° or less.

4. The surface emitting laser according to claim 1, wherein the reflection surface is at least a part of a side surface of the resonator or at least a part of a side surface of a groove provided in the resonator.

5. The surface emitting laser according to claim 1, wherein the reflection surface is an entire side surface of the resonator or an entire side surface of a groove provided in the resonator.

6. The surface emitting laser according to claim 1, wherein the reflection surface is constituted by a cleaved surface.

7. The surface emitting laser according to claim 1, wherein the reflection surface includes at least one of an interface between a semiconductor and air, an interface between a semiconductor and a dielectric, an interface between a dielectric and a semiconductor having a laminated structure, an interface between a semiconductor and a metal, an interface between a dielectric and air, or an interface between a semiconductor and a semiconductor having a laminated structure.

8. The surface emitting laser according to claim 1, wherein the resonator includes a slab waveguide that propagates light in a direction non-parallel to the emission direction.

9. The surface emitting laser according to claim 1, wherein the resonator has a refractive index distribution in a lateral direction of 5% or less.

10. The surface emitting laser according to claim 1, wherein a length of the reflection surface in the emission direction occupies 25% or more of a length of the resonator in the emission direction.

11. The surface emitting laser according to claim 1, wherein the resonator includes a substrate disposed between the first reflecting mirror and the active layer, and
the substrate has at least a part of the reflection surface.

12. The surface emitting laser according to claim 1, further comprising a plurality of the reflection portions.

13. The surface emitting laser according to claim 12, wherein each of the reflection surfaces of at least two of the plurality of the reflection portions is non-parallel to each other.

14. The surface emitting laser according to claim 12, wherein each of the reflection surfaces of at least two of the plurality of the reflection portions is parallel to each other.

15. The surface emitting laser according to claim 12, wherein the active layer has a plurality of the current injection regions, and
the plurality of the reflection portions is provided individually corresponding to the plurality of the current injection regions.

16. The surface emitting laser according to claim 12, wherein the active layer has a plurality of the current injection regions, and
the plurality of the reflection portions is provided in common in the plurality of the current injection regions.

17. The surface emitting laser according to claim 12, wherein the active layer has a plurality of the current injection regions, and
some of the plurality of the reflection portions are provided in common in some of the plurality of the current injection regions, and the others of the plurality of the reflection portions are provided in common in the others of the plurality of the current injection regions.

18. The surface emitting laser according to claim 1, wherein the active layer has a plurality of the current injection regions, and
the reflection portion is provided in common in the plurality of the current injection regions.

19. The surface emitting laser according to claim 1, wherein a shortest distance in an in-plane direction between an outer edge of the first reflecting mirror and the reflection surface is 1000 μm or less.

20. The surface emitting laser according to claim 1, wherein a distance in an in-plane direction between a center of the current injection region and the reflection surface is 1000 μm or less.
